(19) United States
(12) Patent Application Publication
(10) Pub. No.: US 2026/0278188 A1
(43) Pub. Date: Sep. 17, 2026

(54) ARTIFICIAL INTELLIGENCE DETERMINATION OF ENVIRONMENTAL IMPACT AND OPTIMIZATION OF A DESIGN PLAN

(71) Applicant: Togal.AI Inc., Miami, FL (US)

(72) Inventors: Dawn Keller, State College, PA (US); Patrick E Murphy, Miami, FL (US); Johnny Maghzal, Miami, FL (US)

(73) Assignee: Togal.AI Inc., Miami, FL (US)

(21) Appl. No.: 19/161,247

(22) PCT Filed: Nov. 29, 2024
(86) PCT No.: PCT/US24/57967

§ 371 Date: Aug. 30, 2025

Related U.S. Application Data
(60) Provisional application No. 63/604,450, filed on Nov. 30, 2023.

(51) Int. Cl. G06F 30/13; G06F 3/04842; G06Q 30/018

(52) U.S. Cl. CPC G06F 30/13; G06F 3/04842; G06Q 30/018

(57) ABSTRACT

Methods and apparatus operative to quantify building metrics using artificial assessment of an environmental impact, such as climate change and/or carbon control practices. A design plan is represented using multiple dynamic components. Each dynamic component may include a parameter changeable via the user interactive interface. The dynamic components may be arranged in a user interactive interface to form a first set of boundaries, including a respective length and area, and defining at least a portion of a first unit. AI may determine a materials list, methods of construction, distance form a supply source to a job site, supply chain variables, and other variables that are included in an environmental impact analysis. The AI may assess whether a building described in the design plans complies with a relevant environmental impact objective, such, for example, objectives relating to carbon footprint and/or climate change.

### CROSS REFERENCE TO RELATED APPLICATIONS

This Application is a National Phase of International Application Number PCT/US24/57967, filed Nov. 29, 2024 and entitled ARTIFICIAL INTELLIGENCE DETERMINATION OF ENVIRONMENTAL IMPACT AND OPTIMIZATION OF A DESIGN PLAN, which claims the benefit of U.S. Provisional Application No. 63/604,450, filed Nov. 30, 2023, and entitled ARTIFICIAL INTELLIGENCE DETERMINATION OF ENVIRONMENTAL IMPACT AND OPTIMIZATION OF A DESIGN PLAN, the entire contents of each of which are incorporated herein by reference.

### FIELD OF THE INVENTION

The present invention provides improved methods and apparatus for artificial intelligence-based determination of whether a building design is eco-friendly and calls for use of sustainable materials. More specifically, the present invention provides for methods and apparatus that analyze two-dimensional floorplans and uses AI to one or both of: ascertain whether architectural aspects pictorially described in floorplans provides for use of eco-friendly and sustainable materials and construction practices; and to indicate how to reduce negative environmental impact of a construction project.

### BACKGROUND OF THE INVENTION

The construction industry has a reputation for being an industry that is not eco-friendly. This reputation may be due to multiple reasons, such as, for example: high energy consumption wherein construction processes and the operation of buildings consume a significant amount of energy; they rely heavily on resource-intensive materials like concrete and steel; construction and demolition activities generate a large amount of waste; the industry contributes to high levels of greenhouse gas emissions; construction projects are disruptive to natural habitats; and they typically involve high water usage during construction activities.

Buildings account for approximately 40% of global CO2 emissions. Consequently, “green” building initiatives are becoming increasingly attractive to environmentally conscious clients, especially as regulations and incentives in this sector continue to intensify. Sustainable design is becoming a central feature of the construction landscape.

However, green building certification programs such as LEED and BREEAM can take several years to achieve. Collecting data and supporting documentation that meet the requirements of these programs, especially during the design and construction phases, can be very difficult. Currently, the construction process lacks adequate collaboration and review tools, which often forces those involved to rely on manual data collection methods, information synthesis, and compliance review management, which can make the process time consuming and complicated. As a result, builders, architects, engineers, owners, and developers are frequently deterred from pursuing green initiatives.

During conceptual building design, balancing effective structural needs and environmental impact with aesthetics is sometimes more art than science and often involves an inefficient iterative process. Many variables, from materials used, geographic location of a project, wall heights and lengths, and openings to areas and volumes of rooms, heating ventilation and air conditioning systems, climate, and building contents, all contribute to whether a building is eco-friendly. Proposed design plans are typically physically and visually inspected one by one by a highly skilled worker to ascertain compliance with sustainability and eco-friendly goals.

Such manual processes are incredibly time intensive, and it is often difficult to locate skilled personnel with the correct credentials to complete an analysis of a building design for the many types of building use. In addition, different workers may have slightly different approaches and interpretations as to what is sustainable and eco-friendly. As a result, many projects simply abandon pursuit of being eco-friendly and sustainable.

Within the construction industry, there is a growing demand for technology that enhances and supports sustainable design practices. Construction projects that receive favorable sustainability assessments will be more valuable than those that do not, allowing certain construction companies to establish themselves as sustainability leaders early on, however such tools are not currently available.

### SUMMARY OF THE DISCLOSURE

Accordingly, the present disclosure provides methods and apparatus for architects, owners, developers, engineers, compliance reviewers, builders, and other users to analyze two-dimensional (sometimes referred to herein as “2D”) references, such as floorplans, design plans, blueprints, and the like, with the aid of artificial intelligence (sometimes referred to herein as “AI” and an AI platform programmed to accomplish the methods described herein as an “AI Engine”) to ascertain whether a proposed building design has an eco-friendly design and/or may be constructed in an eco-friendly manner using sustainable materials. In some embodiments, a CO2 calculator is generated based on AI analysis, material selection, and EPD information.

Specifically, the present invention uses AI to auto-detect, measure, and classify components of building plans, and ascertain whether the building plans may integrate strategies into the design and construction process to significantly reduce an environmental footprint and improve the sustainability of the project.

The present invention uses an AI Engine to streamline green building and certification process, making it easier for those involved to pursue and accomplish green initiatives. The AI leverages the precision and speed with which the tasks including, but not limited to the following are executed: adjusting plans for sustainability during the construction life cycle; performing carbon calculations and life cycle assessments during the construction life cycle; and reporting on compliance toward LEED and other certifications/credits during the construction life cycle.

In some preferred embodiments, an AI Engine provides user interaction via a single interactive user interface, to automate the evaluation of building plans and materials, provide building alternatives, support collaboration, and report on progress toward green standards and certifications. By leveraging deep learning techniques, the AI Engine converts two-dimensional references, such as blueprints and floor plans, into an actionable user interface that allows architects, engineers, owners, developers, builders, and other users to assess building plans, identify materials, source sustainability metrics, and perform carbon calculations.

The AI Engine streamlines planning during the construction life-cycle by processing two-dimensional references (e.g., blueprints or floor plans) and emulating human perception, learning, problem-solving, and decision-making. The AI Engine's takes two-dimensional references as input and generates pixel patterns through automated processing, turning them into two-dimensional representations. These pixel patterns are then analyzed by AI to mimic human-like understanding and decision-making. This AI analysis can be used to create interactive interfaces that allow users to modify and adjust two-dimensional representations, and analyze the polygons formed by connecting vectors in the two-dimensional references. We believe that a major AI advantage lies in leveraging knowledge from previous work, whether or not a human was involved, hence the importance of integrating our AI with existing databases.

In some specific examples, the present invention uses machine learning and/or artificial intelligence to identify architectural aspects and materials, such as walls, stairwells, floors, ceilings, HVAC components. The present invention identifies such architectural aspects, and other building features and predicts a degree of sustainability and eco-friendly practices for the design.

In some preferred embodiments, the AI Engine is deployed to make recommendations for making changes to the design plans in order to generate a more sustainable building that is eco-friendly.

The present invention reduces inconsistencies in design compliance analysis and mistakes. It also provides consistent feedback on the reasons why a building design is eco-friendly and/or uses sustainable practices and which aspects of a design plan place the building design in a state of being not eco-friendly.

Furthermore, according to some embodiments of the present invention, automated systems generate proposed modifications to achieve a higher degree of sustainability and eco-friendliness.

A two-dimensional reference, such as a design floorplan is input into an AI engine and the AI engine converts aspects of the floorplan into components that may be processed by the AI engine, such as, for example, a rasterized version of the floorplan. The floorplan is then processed with machine learning to specify portions that may be specified as discernable components. Discernable components may include, for example, rooms, residential units, hallways, stairs, dead ends, windows, or other discrete aspects of a building.

A scaling process is applied to the floorplan and size descriptors are assigned to the discernable components. In addition, distances, such as, for example, a distance to an exit from the furthest point in a residential unit are calculated.

In general, the present invention provides for apparatus and methods related to receiving as input design plans (either physical or electronic) and generating one or more pixel patterns based upon automated processing of the design plans. The pixel patterns are analyzed using computerized processing techniques to mimic the perception, learning, problem-solving, and decision-making formerly performed by human workers (such computerized processing techniques are sometimes referred to herein as artificial intelligence or “AI” processing or analysis).

Based upon AI analysis of pixel patterns derived from the two-dimensional references and knowledge accumulated from increasing volumes of analyzed two dimensional references, interactive user interfaces may be generated that allow for a user to modify dynamic design plans of features gleaned from the two-dimensional reference. AI processing of the pixel patterns, based upon the two-dimensional references, may include mathematical analysis of polygons formed by joining select vectors included in the two-dimensional references.

Analysis of pixel patterns and manipulatable vector interfaces and/or polygon-based interfaces is advantageous over human processing in that AI analysis of pixel patterns, vectors and polygons is capable of leveraging knowledge gained from one or both of: a select group and learnings derived from similar previous bodies of work, whether or not a human requesting a current analysis was involved in the previous learnings.

A primary advantage of AI analysis in this scenario is its capacity to analyze complex pixel patterns, vectors, and polygons using knowledge derived from previous experiences. This knowledge is not confined to the work of a single individual but can be harnessed from a select group of experts or shared learnings from similar past projects. This means that the AI system has access to a vast pool of information and insights, enabling it to make informed and effective decisions. Furthermore, the speed at which AI analysis can derive new and improved work based on the current design plan is a remarkable asset. It outpaces human processing capabilities, making the AI Engine a valuable tool for generating innovative solutions and optimizing design plans to be eco-friendly and sustainable construction projects.

In still another aspect, in some embodiments, enhanced interactive interfaces may include one or more of: user definable and/or editable lines; user definable and/or editable vectors; and user definable and/or editable polygons. The interactive user interface may also be referenced to generate diagrams based upon the lines, vectors and polygons defined in the interactive interface. Still further, various embodiments include values for variables that are definable via the interactive user interface with AI processing and human input.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind—including learning from examples and experience, recognizing patterns and/or objects, understanding and responding to patterns in positions relative to other patterns, making decisions, solving problems. The analysis also combines these and other capabilities to perform functions the skilled labor force traditionally performed.

### BRIEF DESCRIPTION OF THE DRAWINGS

The accompanying drawings, which are incorporated into and constitute a part of this specification, illustrate several embodiments of the present invention. Together with the description, these drawings serve to illustrate some aspects of the present invention.

FIG. 1A illustrates method steps that may be implemented in some embodiments of the present invention.

FIG. 1B illustrates a high-level diagram of components included in a system that uses AI to generate an interactive user interface.

FIGS. 2A, 2B, 2C and 2D illustrate a—two-dimensional representation of a floor plan and an AI analysis of same to assess boundaries.

FIGS. 3A-3D show various views of the AI-analyzed boundaries overlaid on the original floorplan including a table illustrated to contain hierarchical dominance relationships between area types.

FIGS. 4A-4B illustrate various aspects of dominance-based area allocation.

FIGS. 5A-5D illustrate various aspects of region identification and area allocation.

FIGS. 6A-6C illustrate various aspects of boundary segmentation and classification.

FIG. 7 illustrates aspects of correction protocols.

FIG. 8 illustrates exemplary processor architecture for use with the present disclosure.

FIG. 9 illustrates exemplary mobile device architecture for use with the present disclosure.

FIGS. 10A-10B illustrate additional method steps that may be executed in some embodiments of the present invention.

FIG. 11 illustrates additional method steps that may be executed in some embodiments of the present invention.

FIG. 12 illustrates LEEDs certification factors that may be included in some embodiments of the present invention.

FIG. 13 illustrates LCA factors that may be included in some embodiments of the present invention.

FIG. 14 illustrates material choice and supply chain factors that may be included in some embodiments of the present invention.

FIG. 15 illustrates a flow chart of some exemplary method steps that may be executed in some embodiments of the present invention.

FIG. 16 illustrates a schematic diagram with multiple areas that may be analyzed by an AI engine according to some embodiments of the present invention.

FIG. 17 illustrates a schematic diagram with additional areas that may be analyzed by an AI engine according to some embodiments of the present invention.

FIG. 17A illustrates a schematic diagram highlighting a tabular display of the spaces and related information.

FIG. 18 illustrates a block diagram of elements that may be included in an AI Engine data file.

FIG. 19 illustrates a flow chart of some exemplary method steps that may be executed in some embodiments of the present invention.

FIG. 20 illustrates geographic and geopolitical aspects that may be included in some AI analysis according to the present invention.

### DETAILED DESCRIPTION

The present invention provides improved methods and apparatus for artificial intelligence-based conversion of a two-dimensional reference, such as a design plan, into an interactive interface for one or both of: indicating whether the design plan may be adapted to an eco-friendly and sustainable construction project and building.

According to the present invention, an AI Engine is deployed to scan a relevant design plan and quantify a whether the design plan meets criteria for certification, local government requirements, produces documentation and evidence of compliance with various sustainability measures; produce documentation relating to requirement for compliance with local environmental impact objectives and regulations that also meet green building requirements; provision and documentation of data and analysis that demonstrates various alternatives to reduce carbon emissions; extensive interdisciplinary collaboration among architects, engineers, contractors, and various stakeholders to ensure each part of the project aligns with green building requirements.

The present invention includes methods and apparatus to analyze a building (or other structure) design based upon automated AI analysis of a two-dimensional reference and applying machine learning to determine if the design adequately supports eco-friendly practices, sustainable choices of building materials, and other sustainability factors.

The present invention may utilize an AI Engine with deep learning architectures, such as neural and adversarial networks, coupled with techniques including forward and reverse propagation. A unique user interactive interface includes editable lines, vectors, and polygons, which are leveraged by users to generate diagrams in real-time, creating improved sustainability analysis documents from two-dimensional references like blueprints or architectural drawings. The AI Engine also works for two-dimensional artifacts that can be converted into pixel patterns (e.g., walls, doorways, doors, plumbing, plumbing fixtures, hardware, fasteners, etc.), and values for variables can be defined through both AI and human input. The two-dimensional references may be represented as images, identifying components, determining their scale, and generating user interfaces to calculate quantities of items needed for construction.

By way of non-limiting illustrative example, an AI Engine process may consider different types of pipes that may be included in a project. Two types of pipes that may be considered as illustrative examples, may include: gravity pipes; and force main or pressure pipes. PVC and reinforced concrete may be materials included as types of materials used in gravity pipes, while PVC and ductile iron may be analyzed for use as force main pipes. An assumed designated service life may be specified, such as, for example, a 100-year service life. The PVC based pipe may be determined to have lower GHG emissions (approximately 45 percent lower than reinforced concrete and 35 percent lower than ductile iron). PVC may also be determined to have the ability to achieve a congruent functional capacity with lighter weight. Concrete and ductile pipes can be determined to require more GHG-intensive transport and installation processes (depending upon a relative distance of travel involved in a supply chain to a specified geolocation. However, ductile-iron pipes may be determined to have comparatively higher recycling rates (about 30 percent) than PVC pipes (about 10 percent). Other factors may also be considered, such as a respective pumping efficiency for force main pipes and environmental factors, such as heating and chilling extremes.

In some embodiments, a whole life carbon assessment may be used to evaluate the total carbon footprint of a proposed and/or existing building or infrastructure project over its entire lifespan. Whole life carbon assessment may ascertain several stages, such as, by way of non-limiting example:

Embodied Carbon: including calculating the carbon emissions associated with the extraction, manufacturing, transportation, and installation of building materials, as well as end-of-life aspects like demolition and recycling. It may be considered an important part of the AI Engine assessment, based upon construction materials such as: steel, concrete, and glass having significant carbon footprints.

Operational Carbon: including calculating carbon emissions resulting from a structure's usage phase. Operational Carbon may include energy converted during heating, cooling, lighting, and operating equipment, appliances, and systems. Operational Carbon may be calculated as a function of a structure's design, insulation, energy sources, and efficiency measures.

Maintenance, Repair, and Replacement: Over a building's life, maintenance activities, repairs, and replacements of various components can contribute to its carbon footprint. Maintenance, Repair, and Replacement may take into account carbon amounts associated with these activities.

End-of-Life: This stage calculates carbon impacts that may result from demolishing a building or other structure and disposing of or recycling materials resulting from the demolition.

Beyond the Building Itself: In some assessments, additional factors such as transportation impacts related to the building (e.g., commuting) and the use of on-site renewable energy sources may be considered.

The goal of a whole life carbon assessment is to identify carbon emissions at each stage of a building's life cycle. By considering these factors from the design phase, it may be possible for the AI Engine and/or user to generate more sustainable choices than those specified in the architectural drawings and/or design plane submitted to the AI Engine, such as, by way of non-limiting example, one or more of: using low-carbon materials, designing for energy efficiency, and planning for end-of-life recycling or reuse. An AI Engine deployed to analyze such factors may become increasingly important in the context of climate change, and to comply with a drive towards net-zero or low carbon targets in the construction industry.

The apparatus and methods disclosed herein are capable of analyzing and allowing a user to understand content of two-dimensional references by identifying pixel patterns, and subsequently transforming them into two-dimensional representations or actionable data. An interactive user interface is created that empowers users to modify and interact with the two-dimensional representations dynamically.

In some embodiments, a CO2 calculator may be generated that is based on AI analysis, material selection, and EPD information.

An interactive interface may be generated that is operative to generate values of variables useful to ascertain whether the submitted design plan meets or exceeds an environmental impact goal pertaining to a specified geographic and/or geopolitical area. The interactive interface may also include specific requirements of an environmental impact objective and indications of whether some or all of the requirements are met. In addition, the interface may include pictorial indications of portions of a design plan that have been associated with specific requirements of the environmental impact objective during the AI analysis. The pictorial indications may include description of why a particular portion meets, exceeds, or does not meet an environmental impact objective.

As described herein, a design plan may be associated with an existing building or a proposed project that includes construction of a building (or other structure, herein collectively referred to as a “building”). Generation of documentation quantifying compliance or non-compliance of a design plan with specific environmental impact goals, such as carbon assessment, is also within the scope of the present invention.

In some embodiments, automated suggested revisions to the design plan to bring the design plan into conformity with specific environmental impact goals are also within the scope of the invention. This innovative feature aims to assist designers and architects in aligning their design plans with environmental impact goals, ultimately enhancing the efficiency of the design and construction process. Automated suggestions for revisions to the design plan represent a dynamic and adaptive approach to ensure that the final design complies with an environmental impact goal such as carbon assessment, underscoring the adaptability and intelligence of the invention. Users can choose automated designs adherent with environmental impact objectives or make personalized modifications. Subsequent environmental impact goals analysis may be conducted based on user-altered designs, allowing flexibility and customization in the design process.

According to the present invention, a controller is operative to execute artificial intelligence (AI) processes and analyze one or more design plans of at least a portion of a building (or other structure) for which an environment impact determination will be generated and provides values for variables used to ascertain a state of compliance based upon descriptive content included in the design plans.

In some embodiments, the design plan may include technical drawings such as blueprints, floor plans, design plans and the like. The AI analysis may include determination of boundaries and/or features indicated in the design plan. The design plan may be a two-dimensional static reference, or a two-dimensional or three-dimensional dynamic reference, such as, but not limited to, a Revit compatible file. This boundary determination may be used to provide useful information about a building such as, one or more of: rooms that comprise a residential unit; an area of an individual room or other area; a distance of travel to a point of egress, a width of a doorway; a width of a path or egress; a dead end path; a perimeter of a defined area; a point furthest from another point (e.g. ; a point furthest from a point of egress); a common path; and the like. Based upon values of parameters derived from a two-dimensional reference, the AI engine may generate additional values related to environmental impact objective, such as, one or more of: carbon impact, pollutant, or other parameters.

Some preferred embodiments include the utilization of the advanced AI engine to rigorously assess design plans for various types of buildings, such as schools, colleges, hospitals, malls, and structures with distinct environmental impact prerequisites (This may be particularly relevant in situations where thoughtful consideration of the surrounding environment is crucial), especially in scenarios involving water, ground, and/or air contamination. This innovative system may be used to ensure that these design plans align carefully with environmental impact goals. The AI engine's primary function may be to determine the values associated with the variables within the design plan, meticulously verifying whether they meet the exacting requirements stipulated by specific environmental impact goals.

AI generated values for parameters may also be useful in a variety of evaluation elements, such as (without limitation): flooring (wood, ceramic, carpet, tile, etc.), structural (poured concrete, steel), walls (gypsum, masonry blocks, glass walls, wall base, exterior cladding), doors and frames (hollow metal, wood, glass), windows glazing, insulation, paint (ceilings and walls), acoustical ceilings, stucco (ceilings and walls), mechanical, plumbing, and electrical aspects. The evaluation elements may be used to calculate an environmental impact to implement a modification to a building design in order to become compliant with an environmental impact objective. The cost may be calculated based upon AI determination of architectural aspects, such as doorways, windows, angles in walls, curves in walls, plumbing fixtures, piping, wiring, electrical equipment, or boxes; duct work; HVAC fixtures and/or equipment; or other component or aspect included in an estimate for work to cause a building to adhere to an environmental impact goal.

In the following sections, detailed descriptions of examples and methods will be given. The description of both preferred and alternative examples, though thorough, are exemplary only. It is understood by those skilled in the art, that various modifications and alterations may be apparent and within the scope of the present invention. Unless otherwise indicated by the language of the claims, the examples do not limit the broadness of the aspects of the underlying invention as defined by the claims.

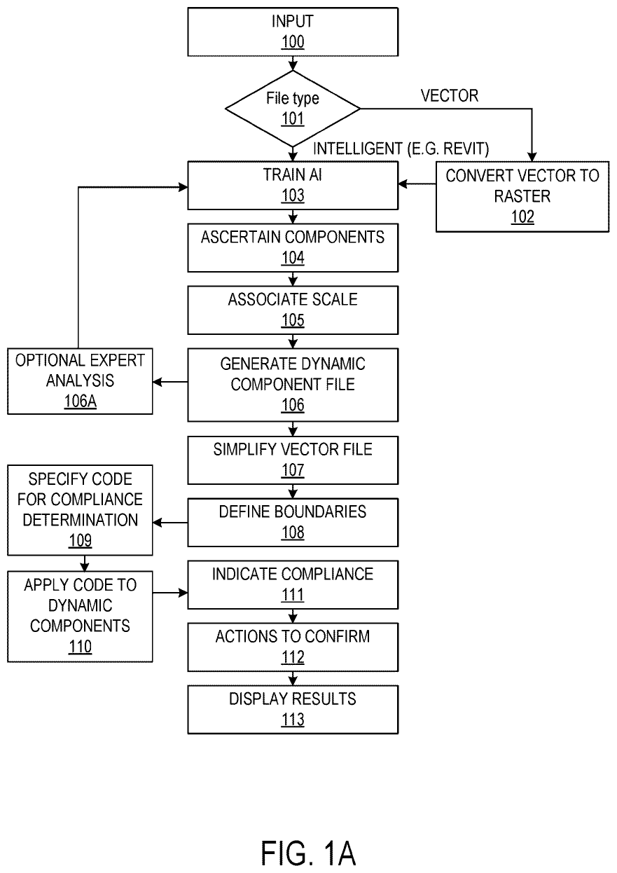

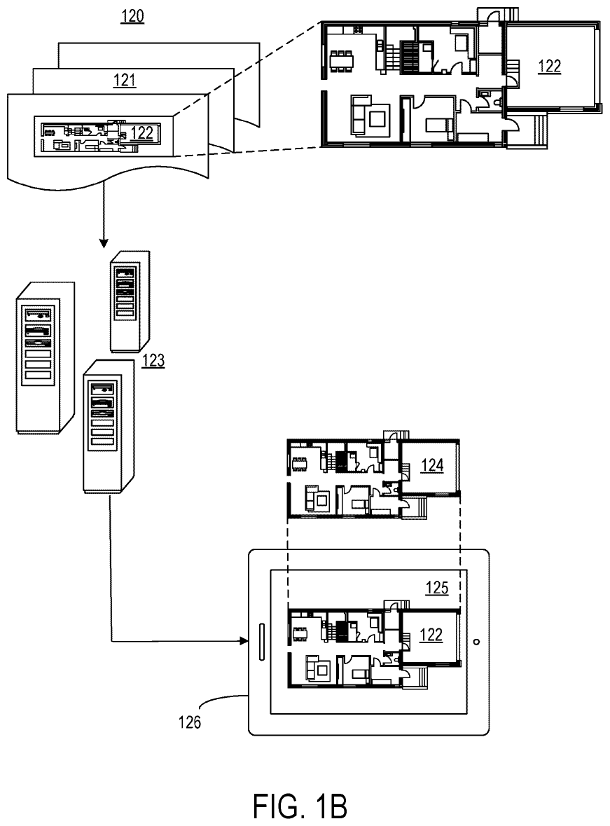

Referring now to FIG. 1A, a general flow diagram showing some preferred embodiments of the present invention as illustrated. At step 100, a design plan (which may be design plan or dynamic architectural design file e.g., a Revit® compatible file) indicating aspects of a building; is input into a controller or other data processing system using a computing device. The design plan may include an item of a known size, such as, by way of non-limiting example, a scale bar that allows a user to obtain a scale of the drawing (e.g., 1″=100′ etc.) or an architectural aspect of a known dimension, such as a wall or doorway of a known length (e.g., a doorway known to be three feet wide).

Input of the two-dimensional reference (i.e., design plan) into the controller may occur, for example, via known ways of rendering an image as a vector diagram, such as via a scan of paper-based initial drawings; upload of a vector image file (e.g., encapsulated postscript file (epf file); adobe illustrator file (ai file); or portable document file (pdf file). In other examples, a starting point for estimation may be drawing file in an electronic file containing a model output for an architectural floor plan. In still further examples, other types of images stored in electronic files such as those generated by cameras may be used as inputs for automated processes that determine adherence with requirements of an environmental impact objective.

In some embodiments, the design plan may be files extensions that include but are not limited to: DWG, DXF, PDF, TIFF, PNG, JPEG, GIF, or other type of file based upon a set of engineering drawings. Some design plans may already be in a pixel format, such as, by way of non-limiting example a two-dimensional reference in a JPEG, GIF or PNG file format. The engineering drawings may be hand drawings, or they may be computer-generated drawings, such as may be created as the output of CAD files associated with software programs such as AutoDesk™, Microstation™ etc. In other examples, such as for older structures, a drawing or other design plan may be stored in paper format or digital version or may not exist or may never have existed. The input may also be in any raster graphics image or vector image format.

The input process may occur with a user creating, scanning into, or accessing such a file containing a raster graphics image or a vector graphics image. The user may access the file on a desktop or standalone computing device or, in some embodiments, via an application running on a smart device. In some embodiments, a user may operate a scanner or a smart device with a charged couple device to create the file containing the image on the smart device.

In some embodiments, a degree of the processing as described herein may be performed on a controller, which may include a cloud server, a standalone computing device or a smart device. In many examples, the input file may be communicated by the smart device to a controller embodied to a remote server. In some embodiments, the remote server, which is preferably a cloud server, may have significant computing resources that may be applied to AI algorithmic calculations analyzing the image.

In some embodiments, dedicated integrated circuits tailored for deep learning AI calculations (AI Chips) may be utilized within a controller or in concert with a controller. Dedicated AI chips may be located on a controller, such as a server that supports a cloud service or a local setting directly.

In some embodiments, an AI chip tailored to a particular artificial intelligence calculation may be configured into a case that may be connected to a smart device in a wired or wireless manner and may perform a deep learning AI calculation. Such AI chips may be configurable to match a number of hidden levels to be connected, the manner of connection, and physical parameters that correspond to the weighting factors of the connection in the AI engine (sometimes referred to herein as an AI model). In other examples, software only embodiments of the AI engine may be run on one or more of: local computers, cloud servers, or on smart device processing environments.

At step 101, the controller may determine if the design plan received into the controller includes a vector diagram. If a file type of the received design plan, such as an input architectural floor plan technical drawing, includes at least a portion that is not already in raster graphics image format (for example that it is in vector format), then the input architectural floor plan technical drawing may be transformed to a pixel or raster graphics image format in step 102. Vector-to-image transforming software may be executed by the controller, or via a specialized processor and associated software.

In some embodiments, the controller may determine a pixel count of a resulting rasterized file. The rasterized file will be rendered suitable for the controller hosting an artificial intelligence engine (“AI engine”) to process, the AI engine may function best with a particular image size or range of image size and may include steps to scale input images to a pixel count range in order to achieve a desired result. Pixel counts may also be assigned to a file to establish the scale of a drawing—for example, 100 pixels equals 10 feet. As an illustrative example, images can be resized to dimensions such as 1024×1024, 512×512, or other dimensions that may be appropriate for the AI engine to function in a better way.

In various examples, the controller may be operative to scale up small images with interleaved average values with superimposed gaussian noise as an example, or the controller may be operative to scale down large images with pixel removal. A desired result may be detectable by one or both of the controller and a user. For example, a desired result may be a most efficient analysis, a highest quality analysis, a fastest analysis, a version suitable for transmission over an available bandwidth for processing, or other metric.

At step 103, training (and/or retraining) of the AI engine is performed. Training may include, for example manual identification of patterns in a rasterized version of an image included in a design plan that correspond with architectural aspects, walls, fixtures, piping, duct work, wiring or other features that may be present in the two-dimensional reference. The training may also include one or more of: identification of relative positions and/or frequencies and sizes of identified patterns in a rasterized version of the image included in the design plan.

In some embodiments, and in a non-limiting sense, an AI engine used to analyze the design plan may be based on a deep learning artificial neural network framework. The AI engine image processing may extract different aspects of an image included in the design plan that is under analysis. At a high level, the processing may perform segmentation to define boundaries between important features. In engineering drawings defined boundaries may be based upon the presence of architectural features, such as walls, doorways, windows, stairs, and the like.

In some embodiments, a structure of the artificial neural network may include multiple layers, such as input layers and hidden layers with designed interconnections with weighting factors. For learning optimization, the input architectural floor plan technical drawings may be used for artificial intelligence (AI) training to enhance the AI's ability to detect what is inside a boundary. A boundary is an area on a digital image that is defined by a user and tells the software what needs to be analyzed by the AI. Boundaries may also be automatically defined by a controller executing software during certain process steps, such as a user query. A boundary within the context of a design plan may signify the presence of a wall. Using deep artificial neural networks, original architectural floor plans (along with any labeled boundaries) may be used to train AI models to make predictions about what is inside a boundary. In exemplary embodiments, the AI model may be given over ~50,000 similar architectural floor plans to improve boundary-prediction capabilities.

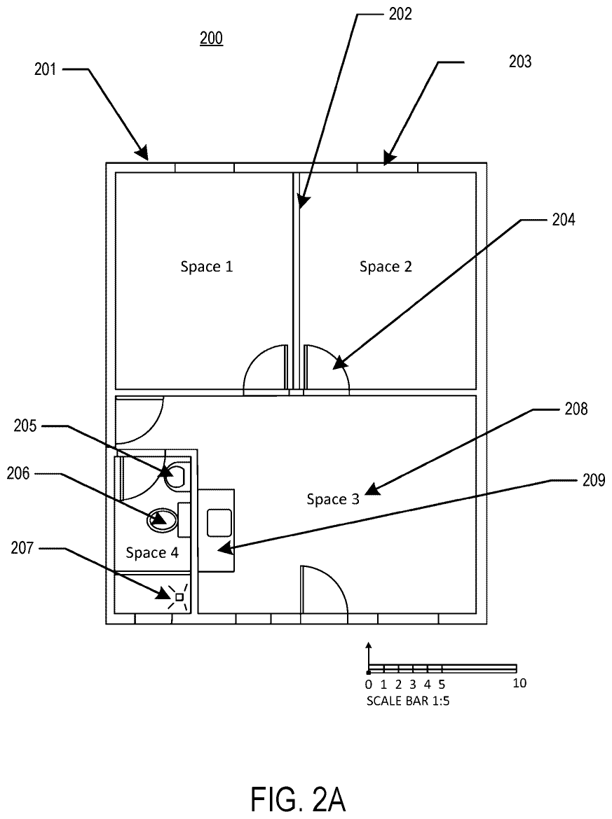

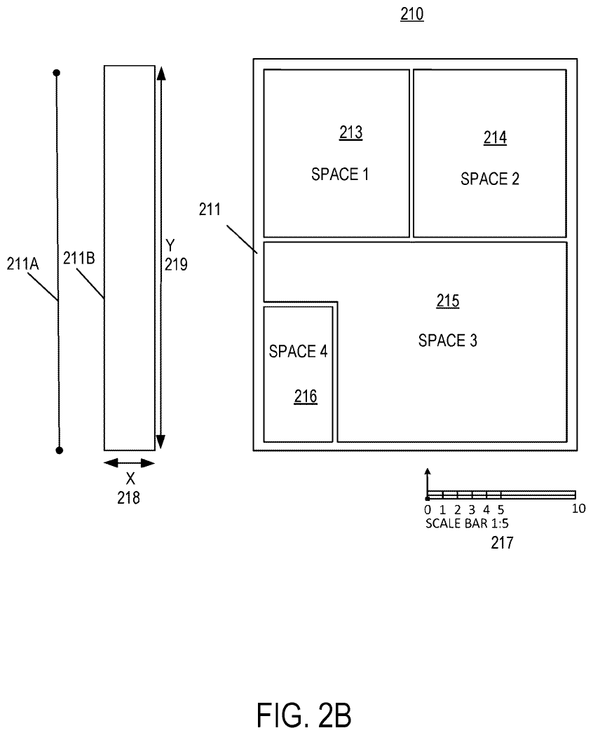

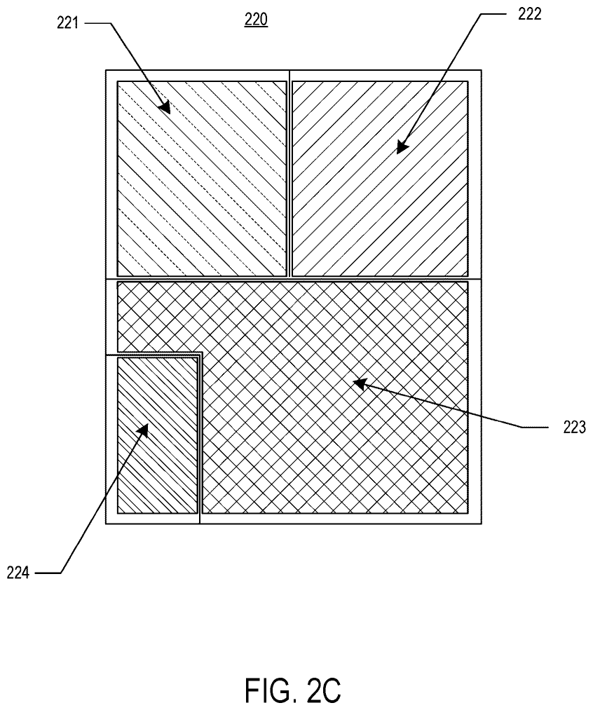

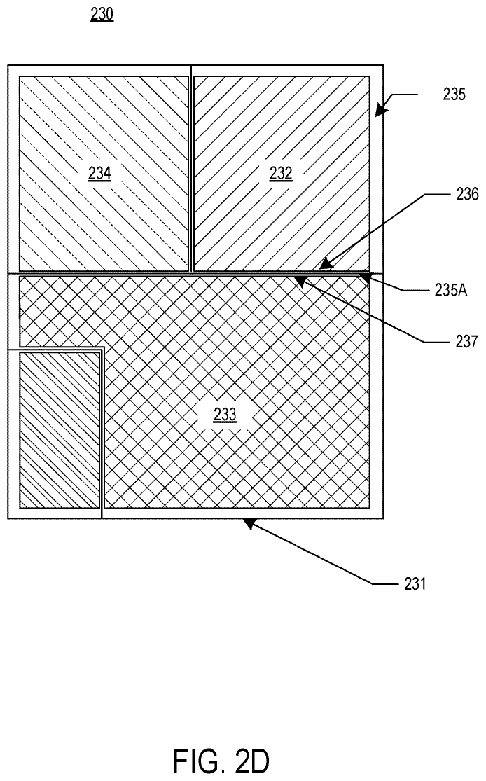

In some embodiments, a training database may utilize a collection of design data that may include one or more of: a combination of a vector graphic two-dimensional references such as floor plans and associated raster graphic version of the two-dimensional references; raster graphic patterns associated with features; and a determination of boundaries may be automatically or manually derived. (An exemplary AI-processed two-dimensional reference that includes a design plan and/or a floorplan 210, with boundaries 211 predicted, is shown in FIG. 2B, based on the floorplan of FIG. 2A.)

In still another aspect, in some embodiments, a controller may access data from various types of BIM and Computer Aided Drafting (CAD) design programs and import dimensional and shape aspects of select spaces or portions of the designs as they are related to a design plan.

At step 104, an AI engine may ascertain features included in the design plan, the AI engine may additionally ascertain that a feature is located within a particular set of boundaries or external to the set of boundaries. Features may include, by way of non-limiting example, one or more of: architectural aspects, fixtures, duct work, wiring, piping, or other item included in a two-dimensional reference submitted to be analyzed. The features and boundaries may be determined, for example, via algorithmically processing an input design plan image with a trained AI model. As a non-limiting example, the AI engine may process a raster file that is converted for output as an image file of a floorplan (as illustrated in FIG. 2B, a boundary is represented as line, a boundary may also be represented as a polygon, which may be a patterned polygon or other user discernable representation, such as a colored line etc.). Features may also be designated on a user interface. A feature may be represented via an artifact, such as, for example, one or more of: a point, a polygon, an icon, or other shape.

At step 105, a scale (e.g., FIG. 2B item 217) is associated with the two-dimensional reference. In preferred embodiments, the scale is based upon a portion of the two-dimensional reference dedicated for indicating a scale, such as a ruler of a specific length relative to features included in a technical drawing included in the two-dimensional reference. The software then performs a pixel count on the image and applies this scale to the bitmapped image. Alternatively, a user may input a drawing scale or dimension for a particular image, building component, a wall, a boundary, a drawing, or other two-dimensional reference. The drawing scale, may for example, be in inches: feet, centimeters: meters, or any other appropriate scale.

In some embodiments, a scale may be determined by manually measuring a room, a component, or other empirical basis for assessing a scale (including the ruler discussed above). Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference (or design plan) and proportioned according to that length. The known length of the wall can be determined from the markings or text on the design plan or can be specified by a user as an input. A known length or width of any other building component can be determined or entered by the user. Based on such known length or width of one building component, the scale can be proportioned, and dimensions of other building components can be calculated.

At step 106, a controller is operative to generate an interactive user interface with dynamic components that may be manipulated by one or both of user interaction and automated processes. Any or all of the components in a user interface may be converted to a version that allows a user to modify an attribute of the components, such as the length, size, beginning point, end point, thickness, or other attribute. In some embodiments, a boundary may be treated as a component or a wall and manipulated in a similar manner.

Other components included in the user interface may include, one or more of: AI engine predicted components, user training aspects, and AI training aspects. In some non-limiting examples of the present invention, a generative adversarial network may include a controller with an AI engine operative to generate a user interface that includes dynamic components. In some embodiments, a generative adversarial network may be trained based on a training database for initial AI feature recognition processes.

An interactive user interface may include one or more of: lines, arcs, or other geometric shapes and/or polygons. In some embodiments, the geometric shapes and/or polygons may comprise boundaries. The components may be dynamic in that they are further definable via user and/or machine manipulation. Components in the interactive user interface may be defined by one or more vertices. In general, a vertex is a data structure that can describe certain attributes, like the position of a point in a two-dimensional or three-dimensional space. It may also include other attributes, such as normal vectors, texture coordinates, colors, or other useful attributes.

At step 107, some embodiments may include a simplification or component refinement process that is performed by the controller. The component refinement process is functional to reduce a number of vertices generated by a transformation process executed via a controller generating the user interface and to further enhance an image included in the user interface. Improvements may include, by way of non-limiting example, one or more of: smooth an edge, define a start, or end point, associate a pattern of pixels with a predefined shape corresponding with a known component or otherwise modify a shape formed by a pattern of pixels.

In addition, some embodiments that utilize the recognition step transforms features such as windows, doorways, vias and the like to other features and may remove them and/or replace them as elements—such as line segments, vectors, or polygons referenceable to other neighboring features. In a simplification step, one or more steps the AI performs (which may in some embodiments be referred to as an algorithm or a succession of algorithms) may make a determination that wall line segments, and other line segments represent a single element and then proceeds to merge them into a single element (line, vector, or polygon). In some embodiments, straight lines may be specified as a default for simplified elements, but it may also be possible to simplify collections of elements into other types of primitive or complex elements including polylines, polygons, arcs, circles, ellipses, splines, and non-uniform rational basis spline (NURBS) where a single feature object with definitional parameters may supplant a collection of lines and vertices.

The interaction of two elements at a vertex may define one or more new elements. For example, an intersection of two lines at a vertex may be assessed by the AI as an angle that is formed by this combination. As many construction plan drawings are rectilinear in nature, it may be that the simplification step inside a boundary can be considered a reduction in lines and vertices and replacing them with elements and/or polygons.

In another aspect, in some embodiments, one or both of a user and a controller may indicate a component type for a boundary. Component types may include, for example, one or more of line segments, polygons, multiple line segments, multiple polygons, and combinations of line segments and polygons.

At step 106A, in some embodiments, components presented in the interactive user interface may be analyzed by a user and refinements may be made to one or more components (e.g., size, shape and/or position of the component). In some embodiments, user modifications may also be input back to the AI engine to train the AI engine. User modifications provided back to the AI Engine may be referenced to make subsequent AI processes more accurate, efficient, fast, trained and/or enable additional types of AI processes.

At step 108, a controller (such as, by way of non-limiting example, a cloud server) operative as an AI engine may create AI-predicted dynamic boundaries that are arranged to form a representation of the submitted design plan that does not include the boundaries that bound it.

In various embodiments, a boundary may be used to define a unit, such as a residential unit, a commercial office unit, a common area unit, a manufacturing area, a recreational area, a dining area, or other area delineated according to a permitted use.

Some embodiments include an interface that enables user modifications of boundaries and areas defined by the modified boundaries. For example, a boundary may be selected and “dragged” to a new location. The user interface may enable a user to select a line end, a polygon portion, an apex, or other convenient portion and move the selected portion to a new position and thereby redefine the line and/or polygon. An area that includes a boundary as a border will be redefined based upon the modification to the boundary. As such, an area of a room or unit may be redefined by a user via the user interface. Changing an area of a room and/or unit may in turn be used as a basis for modifying an occupant load, defining an egress path, classifying a space, or other purpose.

For example, a change in a boundary may make an area larger. The larger area may be a basis for an increase in occupancy load. The larger area may also result in a longer path from the furthest point in the defined area to a point of egress (e.g., if a user chooses to use a worst case in determining an egress route). Empowering users with flexibility, the present invention allows for seamless modifications to room boundaries, lines, and polygons, enabling the alteration of shapes and sizes to adhere to an environmental impact objective with automated revision suggestions to design plans. This dynamic feature not only ensures adherence with regulatory standards but also caters to user preferences or priorities, allowing them to retain the opulence and aesthetic appeal of their spaces. Whether it is aligning with an environmental impact objective requirement or enhancing the overall user experience by accommodating individual tastes, the present invention offers a harmonious blend of functionality and personalization. Users can effortlessly tailor their rooms to meet both regulatory guidelines and their own vision, striking a balance between adherence and the creation of spaces that truly reflect their unique style and preferences.

At step 109, one or both of the user and an automated process on a controller may specify an environmental impact objective for which an adherence determination based upon the AI generated boundaries. In some embodiments, a selection of a set of an environmental impact objectives to apply to the floor plan may be automated, for example, based upon a geographic or geopolitical area in which the building resides or will be constructed. In other embodiments, a user may specify a set of an environmental impact objective, such as, for example, a drop-down menu may indicate available an environmental impact objectives and a user may select one or more an environmental impact objective to apply to the floor plan.

Accordingly, by way of non-limiting example, a user may select that a set of floorplans to be analyzed with the AI engine to assess adherence with LEEDS, carbon credit requirements, or other guideline, regulation, or standard or listing selected by a user.

In specific contexts such as building structures where specialized environmental impact objective considerations are imperative, users can harness the power of the AI engine to conduct comprehensive analyses of design plans. The adaptability of the AI engine may facilitate seamless testing against a spectrum of variables adopted related to an environmental impact objective, providing a robust solution for users navigating the intricate landscape of diverse building requirements. This functionality not only streamlines the analysis process but also serves as a proactive tool for architects, designers, and builders to preemptively address and meet the stringent standards that govern construction projects, environments, and supply chain.

At step 110, a set of parameters for a selected set of environmental impact criteria is applied to some or all of the dynamic components generated via the AI engine.

At step 111, the user interface or other output may be caused to display an indication of an environmental impact of a design plan, environmental impact, may include, by way of non-limiting example, a carbon footprint associated with one or both of constructing a building or other structure described by the design plan. In some embodiments, an alphanumerical value, or other weighted variable may be associated with an indicated environmental impact. Some specific embodiments may include a LEED (leadership in Energy and Environment Design) certification, such as, by way of non-limiting example: platinum, gold, silver, and/or certified certification.

In generating a value, such as for a variable, the AI engine and/or the user may need to designate that one or more boundaries define a specific type of area, such as a bedroom, a hallway, or a stairwell. Each specific type of area may have specified variables associated with it. By way of non-limiting example, the user interface may employ an indicator for a material type and/or construction method and/or geographic source of a material and/or equipment involved in the construction and/or deployment of the structure for a designated use. In other embodiments, the user interface may visually indicate portion of the design plan that was referenced in determining a material and construction process.

Some specific embodiments may include a first portion of a user interface with delineated conditions for material and construction modality, such as, for example, a listing of sections of a structure, an ability for a user to select a specific section of the structure, and a link that brings up an interface with visual indicators illustrating a carbon impact or other environmental factor with the user selected section of a structure. Incorporating similar visual indicators to structure assessment, the present invention may introduce a user-friendly color-coding scheme that simplifies the interpretation of structure adherence within an environmental initiative. This innovative feature may allow users to swiftly identify and distinguish between environmentally friendly and environmentally adverse elements of a design plan.

For instance, by way of non-limiting example, a red-colored portion within the design plan signals environmentally hostile materials and/or construction practices, offering an immediate visual cue for areas that require attention or modification, and an option of a user to receive automated suggestions for modification generated by the AI Engine. Conversely, a green color may signify adherence, providing a quick and easily understandable visual confirmation of adherence to an environmental objective. This intuitive color-coding system enhances interpretation of environmental impact of a design, and streamlines an associated decision-making process, empowering users to efficiently navigate and address areas of concern within a design plan in an efficient manner. The interactive user interface may also display information about which specific environmental impact requirements are not met and a corresponding quantity of such discrepancies.

At step 112, in another aspect, the present invention may use the AI Engine to generate suggested modifications to a design plan in order to transition the design plan from a state of adverse environmental impact to a state of positive environmental impact.

At step 113, a conclusion of whether a design plan meets certification levels or other designation of environmental impact may be displayed on the user interface in an integrated fashion in relation to a replication of the two-dimensional reference (such as the design plan, architectural floor plan or technical drawing). The user interface may also be shown in a form that includes user modifiable elements, such as, but not limited to: polylines, polygons, arcs, circles, ellipses, splines, line segments, icons, points, and other drawing features or combinations of lines and other elements.

Referring now to FIG. 1B, a high-level diagram illustrates components included in a system 120 that uses AI to generate an interactive user interface 125 and programmable apparatus (controller) 123 operative to execute method steps useful in determining adherence for a design plan or other architectural description.

According to some embodiments of the present invention, a two-dimensional reference 121, such as a design plan, floor plan, blueprint, or other document includes a pictorial representation 122 of at least a portion of a building. The pictorial representation 122 may include, for example, a portable document format (PDF) document, jpeg, png, or other essential non-dynamic file format, or a hardcopy document. The pictorial representation 122 includes an image descriptive of architectural aspects of the building, such as, by way of non-limiting example, one or more of: walls, doors, doorways, hallways, rooms, residential units, office units, bathrooms, stairs, stairwells, windows, fixtures, real estate accouterments, and the like.

The two-dimensional reference 121 may be electronically provided to a controller 123 running an AI engine. The controller 123 may include, for example, one or more of: a cloud server, an onsite server, a network server, or other computing device, capable of running executable software and thereby activating the AI engine. Presentation of the two-dimensional reference may include, for example, scanning a hardcopy version of the two-dimensional document into electronic format and transmitting the electronic format to the controller 123 running the AI engine.

According to the present invention, data of various types and conveyed in disparate modalities is received into an AI engine. The AI engine may use raw data, manipulated data, interpreted data, new data and data types generated from existing data. Data may include one or more of: text, image, numerical, pixel patterns, polygons, vectors, molecular, neural, digital, and analog data modalities. Data sources may include one or more of: a user portal; Internet accessible resources; shipping data, fuel use tracking; manufacturer data; product data sheet; geolocation device, or other receptacle or generator of data related to material use in a building or other construction project.

AI engine processing may include one more of: converting image data to pixel patterns and/or polygon patterns, manipulating pixel patterns and/or polygon patterns, analyzing pixel patterns and/or polygon patterns, optical character recognition, alphanumeric analysis, symbol recognition and the like. Proposed action strategies, protocols and opportunities may be associated with an ascertained state.

The present invention provides for the deployment of computational frameworks combining disparate aspects of technology to perform tasks that are beyond the ability of traditional design and build systems or human intelligence. These systems aggregate large volumes of disparate data that may or may not be intuitively linked to building design, carbon footprint, eco-friendliness, supply chain availability, anticipated ambient climate conditions, measured ambient climate conditions, building activities, or other data source, and utilize multiple modalities data manipulation, algorithms, and statistical models to generate proposed action strategies for a patient (or group of similarly situated patients). Modalities of data manipulation may include, but are not limited to:

Machine Learning (ML): A subset of AI where systems learn from data. Instead of being explicitly programmed, they adjust their operations to optimize for a certain outcome based on the input they receive.

Deep Learning: A subfield of ML using neural networks with many layers (hence “deep”) to analyze various factors of data, such as, for example, convolutional neural networks (CNNs) used in image recognition. For example, convolutional neural networks may receive as input image data from scans of various types and generate pixel patterns representative of the scans. The pixel patterns may be compared to a library of other pixel patterns and/or manipulated to emulate progression of a disease state and/or a treatment protocol over time. Successful eco-friendly alternatives based upon Deep Learning patterns may be identified and included in a proposed design and build strategy based upon the Deep Learning findings without ever having to associate the pixel patterns with a particular design issue.

Natural Language Processing (NLP): Allows systems to understand, interpret, and generate human language. NLP may provide interpretations of voice data. Voice data may be made accessible, for example, via recording made during design plan review and assessment and/or during supply chain activities.

Robotics: Robots may operate using AI principles, enabling the robots to perform tasks in accurate, specific, and consistent ways. Robots may also be utilized during data collection, such as during building scans (e.g., 3D image acquisition scans), as built measurement acquisition, infrared heat image acquisition and the like.

Knowledge Representation: The methods and apparatus taught herein may receive data in a native or enhanced state and manipulate and transform the received data into a machine learning understandable form.

Reasoning: The methods and apparatus taught herein may solve deploy logical deduction via expert systems and the like to facilitate decision-making.

Perception: The methods and apparatus taught herein may use algorithms and complex relational processes that allow machines to interpret disparate data sets, including image data, sound data, and alphanumeric data.

Apparatus and methods may be arranged to form one or more of: Neural Networks; Genetic Algorithms; Expert Systems; and Reinforcement Learning.

In some embodiments, GPUs may be used to accomplish large-scale machine learning models using parallel processing capabilities. Hardware accelerators may be utilized for deep learning tasks. In some embodiments, tensor processing units and/or neuromorphic computing mechanisms may be used to analyze data sets. Cloud platforms may be used with AI processes, such as deep learning that require significant computational resources.

Electronic and/or electromechanical apparatus may provide data to be processed using the methods and apparatus presented herein. Apparatus may include, by way of nonlimiting example, one or more of: three-dimensional (3D) image scans, heat imaging acquisition, design plan scanners, building monitoring electronic sensors, drone-based electronic scans, satellite-based data acquisition or other means of acquiring data that may be transformed into digital and/or analog data sets.

Some AI Engine 101 generated treatment strategies may include suggested courses of action that may be weighted based upon one or more of: projected effectiveness; timing; geographic location and a material's ability to be transported; cost; and project criticality, including timeline relative to other actions and/or tasks that may be completed, such as for example, a sequence of construction steps, inspections, and financing requirements.

The controller is operative to generate a user interface 125 on a user computing device 126. The user computing device may include a smart device, workstation, tablet, laptop or other user equipment with a processor, storage, and display.

The user interface 125 includes a reproduction of the pictorial representation 122 and an overlay 124 with one or more user manipulatable components, such as, by way of non-limiting example: boundaries, line segments, polygons, images, icons, points, and the like. The line segments may have calculated lengths that may be mathematically manipulated and/or summarized. Aspects such as polygons, line segments, shapes, icons, and points may be counted, added, subtracted, extrapolated, and have other functions performed on them.

In addition, renditions of the user interface 125 may be created and saved, and/or communicated to other users, or controllers, compared to subsequent interface renditions, archived and/or submitted to additional AI analysis.

In some embodiments, a first user interface 125 rendition may be modified by a user to create a second user interface 125 and submitted to AI analysis to ascertain environmental impact with a selected set of requirements. Some embodiments may also calculate costs, expenses, man hours or other variable associated with changes to a design plan in order to bring the design plan into alignment with environmental impact goals. Change order renditions provided as options to bring a design plan into alignment with environmental impact goals with a selected set of requirements may also be provided with a unique identifier, time and/or date stamped to create a continuum of work, as related to original projects and alignment with environmental impact goals-initiated changes. Each of the items in the continuum of work may be stored and subsequently used for ascertaining eventual alignment with environmental impact goals of a building with each selected environmental impact objective.

Referring now to FIG. 1C, a design plan is illustrated with multiple dwelling units 135-136 and a path of travel 131 from a farthest point in the unit, and a blow up of the stairwell 132A of a portion of the design plan determined by the AI engine to be a stairwell 132. The blowup of the stairwell 132A includes a dimension 134 indicating that ½ of the stairwell 132A (typically either ascending or descending side of a stairwell 132A) is equal to five feet. A dimensional end cap 134A is illustrated and indicates one side of the dimension 134.

In some embodiments, the end cap 134A will be placed on a user interface with dynamic components 130 by a controller as a result of a determination by an AI engine in communication with the controller. Furthermore, some embodiments allow placement of the end cap 134A as a result of a user action. Still further, one or both of the controller and the user may adjust placement of an end cap 134A initially placed by either the controller and/or the user.

According to the present invention, once a dimension 134 has a value associated with it (or dimension of a component is already known or calculated from any other component having known dimension in the design plan), the dimension may be used to extrapolate other dimensions, such as, for example, one or more of: a length and/or width of a wheelchair accessible ramp 133; a length 131A of a path 131, an area of a unit 135-136 or other distance and/or area. As discussed in more detail herein, a length 131A of a path 131 may be used to calculate a length of a path from a furthest point to a point of egress (where the point of egress may be the stairwell 132).

The illustrated end cap 134A is shown as a line, other end caps 134A may also be within the scope of the present invention that may better suit a particular aspect on a design plan interface 125, such as, by way of non-limiting example, one or more of: a perpendicular corner, a dot, an arrow, a circle, angled lines joined at a defined number of degrees, such as thirty degrees, forty-five degrees, ninety degrees or an angle provided by one or both of the AI engine and the user.

Referring now to FIG. 1D, tables 140 list exemplary parameters that may be values for variables used in AI engine processes to determine whether a design plan is in environmental impact. As described herein, a design plan may be defined as one or more areas or regions. An area may be associated with variables. Values for the variables may be generated by the AI engine and/or provided via user input and may be a value representative of a relevant environmental impact objective, or a best practice. Non-limiting examples of variables include: a function of the area 141, which may have an exemplary value of: kitchen, dining, bedroom, bathroom, living room, meeting room, office, lounge, or other descriptor of a space that may be one or more “rooms” in a Unit 143. A ‘Type” variable 142 may indicate a sanctioned use for the area, such as, for example: residential, business, assembly, storage, clean room, retail, medical, school, hospital, and the like. An area 144 may be indicated as square feet, square meters, square yards, or other designated measurement unit for area. The area 144 represents the space allocated for a specific Unit 144 having an associated function 141. For example, a Kitchen (function 141) for a residential (type 142) building in a Unit 1 (143) may have an area of 456 square feet (area 144).

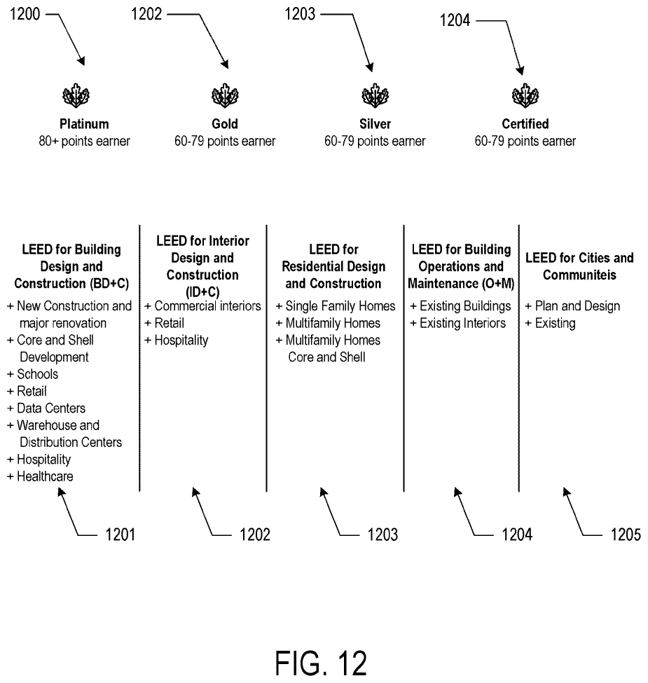

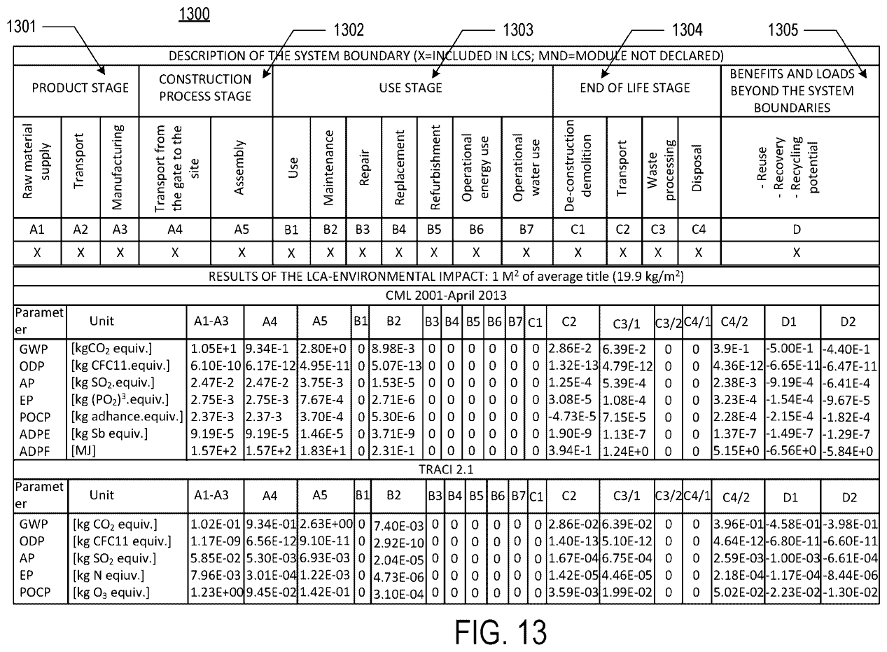

A Perimeter 145 includes a value for distance measurement. An area per occupant 146 may be indicated as square feet per occupant, such as 10 to 30 square feet. The area per occupant may be determined via the AI engine based upon a geopolitical location the building represented by the design plan will be built in, or an input by a user. A maximum occupancy 147 value may be calculated from the area 144 value and the sq. ft per occupant 146 value. The Distance to a front door 148 may be calculated by the AI engine by analyzing a layout (design plan) and available paths for an occupant to travel in order to exit (as described in more detail with regards to FIGS. 12A-12C.

Other variables, such as longest distance per unit 149 value and longest distance per type 150 value may include values for variables representative of one or both of: distances calculated by the AI engine based upon analysis of a design floor plan. Aggregations 151-153 may include a sum of some or all values for variables in a given class, such as, for example an aggregated sum of areas 144, aggregated maximum occupancy 152, and aggregated longest distance 153.

Referring now to FIG. 2A, a given two-dimensional reference 200 may have a number of elements that an observer and/or an AI engine may classify as features 201-209 such as, for example, one or more of: exterior walls 201; interior walls 202; doorways 204; windows 203; plumbing components, such as sinks 205, toilets 206, showers 207, water closets or other water or gas related items; kitchen counters 209 and the like. The two-dimensional references 200 may also include narrative or text 208 of various kinds throughout the two-dimensional references.

Identification and characterization of various features 201-209 and/or text may be included in the input two-dimensional references. Generation of values for variables included in generating a bid may be facilitated by splitting features into groups called ‘disparate features’ 201-209 and boundary definitions and generation of a numerical value associated with the features, wherein numerical values may include one or more of: a quantity of a particular type of feature; size parameters associated with features, such as the square area of a wall or floor; complexity of features (e.g. a number of angles or curves included in a perimeter of an area; a type of hardware that may be used to construct a portion of a building, a quantity of a type of hardware that may be used to construct a portion of the building; or other variable value.

In some embodiments, a recognition step may function to replace or ignore a feature. For example, for a task goal of the result shown in FIG. 2B, features such as windows 203, and doorways, 204, may be recognized and replaced with other features consistent with exterior walls 201 or interior walls 202 (as shown in FIG. 2A). Other features may be removed, such as the text 208, the plumbing features and other internal appliances and furniture which may be shown on drawings used as input to the processing. Again, such feature recognition may be useful to accomplish other goals, but for a goal of boundary 211 definition that delineates a floorplan 210 as illustrated in FIG. 2B a pictorial representation may be purposefully devoid of such features, as illustrated.

Referring now to FIG. 2B, a boundary 211 is illustrated around a grouping of defined spaces 213-216. Spaces are areas within a boundary (which may include, but are not limited to rooms, hallways, stairwells etc.).

FIG. 2B illustrates an AI predicted boundary 211 based upon an analysis of the floorplan 210 illustrated in FIG. 2A. A transition from FIG. 2A to FIG. 2B illustrates how an AI engine successfully distinguishes between wall features and other features such as a shower 207, kitchen counter 209, toilet 206, bathroom sink 205, etc. shown in FIG. 2A.

In another aspect, in some embodiments, a boundary may include a polygon 211B. A polygon may be any shape that is consistent with a design submitted for AI analysis. For example, a rectangular polygon 211B may be based upon a wall segment 211A and have a width X 218 and a length Y 219. Boundaries that include polygons are useful, for example in creating a three-dimensional representation of a design plan.

According to the present invention, a boundary may be represented on a user interface as one or both of: one or more line segments, and one or more polygons. In addition, a feature may be represented as a single point, a polygon, an icon, or a set of polygons. In some embodiments, a point may be placed in a centroid position for the feature, and the centroid points may be counted, summarized, subtracted, averaged, or otherwise included in mathematical processes.

In some embodiments, an analytical use for a boundary may influence how a boundary is represented. For example, determination of a length of a wall section, or size of a feature may be supported via a boundary that includes a line segment. A count of feature type may be supported with a boundary that includes a single point or predefined polygon or set of polygons. Extrapolation of a two-dimensional reference into a three-dimensional representation may be supported with a boundary that includes polygons.

A scale 217 may be used to indicate a size of features included in a technical drawing included in the two-dimensional reference. As indicated above, executable software may be operative with a controller to count pixels on an image and apply a scale to a bitmapped image. Alternatively, a user may input a drawing scale for a particular image, drawing or other two-dimensional reference. Typical units referenced in a scale include inches: feet, centimeters: meters, or any other appropriate unit.

In some embodiments, a scale 217 may be determined by manually measuring a room, a component, or other empirical basis for assessing a relative size. Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length.

Referring now to FIG. 2C, a user interface 220 is illustrated with multiple regions 221-224. The multiple regions 221-224 may be presented via different hatch representations or other distinguishing pattern (in some embodiments regions may also be represented as various colors etc.). During training of AI engines, and in some embodiments, when a submitted design drawing includes highly customized or unique features, a user may wish to adjust an automated identification of boundaries and automated filling of space within the boundaries.

During training of processes executed by a controller, such as those included in an AI engine made operative by the controller, and in some embodiments, when a submitted design drawing includes highly customized or unique features, an automated identification of boundaries and automated filling of space within the boundaries may be included in the interactive user interface may not be according to a particular need of a user. Therefore, in some embodiments of the present invention, an interactive user interface may be generated that presents a user with a display of one or more boundaries and pattern or color filled areas arranged as a reproduction of a two-dimensional reference input into the AI engine.

In some embodiments, the controller may generate a user interface 220 that includes indications of assigned vertices and boundaries, and one or more filled areas or regions with user changeable editing features to allow the user to modify the vertices and boundaries. For example, the user interface may enable a user to transition an element such as a vertex to a different location, change an arc of a curve, move a boundary, of change an aspect of polylines, polygons, arcs, circles, ellipses, splines, NURBS or predefined subsets of the interface. The user can thereby “correct” an assignment error made by the AI engine, or simply rearrange aspects included in the interface for a particular purpose or liking.

In some embodiments, modifications and/or corrections of this type can be documented and included in training datasets of the AI model, also in processes described in later portions of the specification.

Discrete regions may be regions associated with an estimation function. A region that is contained within a defined wall feature may be treated in different ways, such as ignoring all area within a boundary or counting all area within a boundary (even though regions do not include boundaries). If the AI engine counts the area, it may also make an automated decision on how to allocate the region to an adjacent region or regions that the region defines.

Referring to FIG. 2D, an exemplary user interface 230 illustrates a user interface floorplan model 231 with boundaries 236-237 between adjacent regions 233-234 with interior boundaries 236-237 that may be included in an appropriate region of a dynamic component 130. The AI may incorporate a hierarchy where some types of regions may be dominant over others, as described in more detail in later sections. Regions with similar dominance rank may share space, or regions with higher dominance rank may be automatically assigned to a boundary. In general, a dominance ranking schema will result in an area being allocated to the space with the higher dominance rank. In some embodiments, a dominance rank will allocate an area that may be used in determining an occupancy load. Moreover, in those embodiments that analyze a dynamic file (such as, for example, a Revit® compatible file) a dominance rank may be included, or added to, one or more dynamic features and be modified as the dynamic feature is modified. In some embodiments, the incorporation of a dominance rank may be instrumental in delivering automated suggestions for the revision of design plans. The dominance rank may serve as a strategic guide, steering the focus towards regions of higher dominance rank. For instance, regions with a higher dominance rank are recommended to remain as unchanged as possible in the suggested revisions besides making sure that the revised designs of the regions comply with an environmental impact objective e.g., not only for the sake of environmental impact but also to preserve the integral aspects of the original designs of the higher dominance regions. This approach prioritizes regions with a higher dominance rank on the overall design, ensuring that modifications align with both regulatory requirements and the foundational elements that contribute significantly to the design's integrity. By intelligently discerning and preserving key elements, this embodiment may optimize the revision process, maintaining a delicate balance between alignment with environmental impact goals and the preservation of the design's dominant features.

In some embodiments, an area 235A between interior boundaries 236-237 and an exterior boundary 235 may be fully assigned to an adjacent region 232-234. An area between interior boundaries 235A may be divided between adjacent regions 232-234 to the interior boundaries 236-237. In some embodiments, an area 235A between boundaries 236-237 may be allocated equally, or it may be allocated based upon a dominance scheme where one type of area is parametrically assessed as dominant based upon parameters such as its area, its perimeter, its exterior perimeter, its interior perimeter, and the like. Parameters may also be based upon items that are automatically counted using AI analysis of pixel patterns that identifies a pattern as an item, such as, by way of non-limiting example, one or more of: doors or other paths of egress; plumbing fixtures; fixed obstacles; stairs; inclines; and declines.

In some examples, a boundary 235-237 and associated area 235A may be allocated to a region 232-234 according to an allocation schema, such as, for example, an area dominance hierarchy, to a prioritize a kitchen over a bathroom, or a larger space over a smaller space. In some embodiments, user selectable parameters (e.g., a bathroom having parameters such as two showers and two sinks may be more dominant over a kitchen having parameters of a single sink with no dishwasher). These parameters may be used to determine boundary and/or area dominance. A resulting computed floorplan model may include a designation of an area associated with a region as illustrated in FIG. 2. In various embodiments, different calculated features are included in a user interface floorplan model 231 such as features representing aspects of a wall, such as, for example, center lines, the extents of the walls, zones where doors open and the like, and these features may be displayed in selected circumstances.

Some embodiments may also include AI analysis of a dynamic file, such as a Revit or Revit compatible file and/or a raster file with patterns of dots, the AI may generate a likelihood that a region or area represented by one or both of a polygon or pattern of dots, includes a common path or dead end or an area definable for determining an occupancy load, egress capacity, travel distance and/or other factor that may influence a decision on alignment with environmental impact goals.

Once boundaries have been defined a variety of calculations may be made by the system. A controller may be operative to perform method steps resulting in calculation of a variable representative of a floorplan area, which in some embodiments may be performed by integrating areas between different line features that define the regions.

Alternatively, or in addition to method steps operative to calculate a value for a variable representative of an area, a controller may be operative to generate a value for element lengths, which values may also be calculated. For example, if ceiling heights are measured, presented in drawings, or otherwise determined, then volume for the room and surface area calculations for the walls may be made. There may be numerous dimensional calculations that may be made based on the different types of model output and the user-inputted calibration factors and other parameters entered by the user.

In some embodiments, a controller may be provided with two dimensional references that include a series of architectural drawings with disparate drawings representing different elevations within a structure. A three-dimensional model may be effectively built based upon a sequenced stacking of the disparate drawings representing different levels of elevations. In other examples, the series of drawings may include cross sectional representation as well as elevation representation. A cross-section drawing, for example, may be used to infer a common three-dimensional nature that can be attributed to the features, boundaries and areas that are extracted by the processes discussed herein. Elevation drawings may also present a structure in a three-dimensional perspective. Feature recognition processes may also be used to create three-dimensional model aspects.

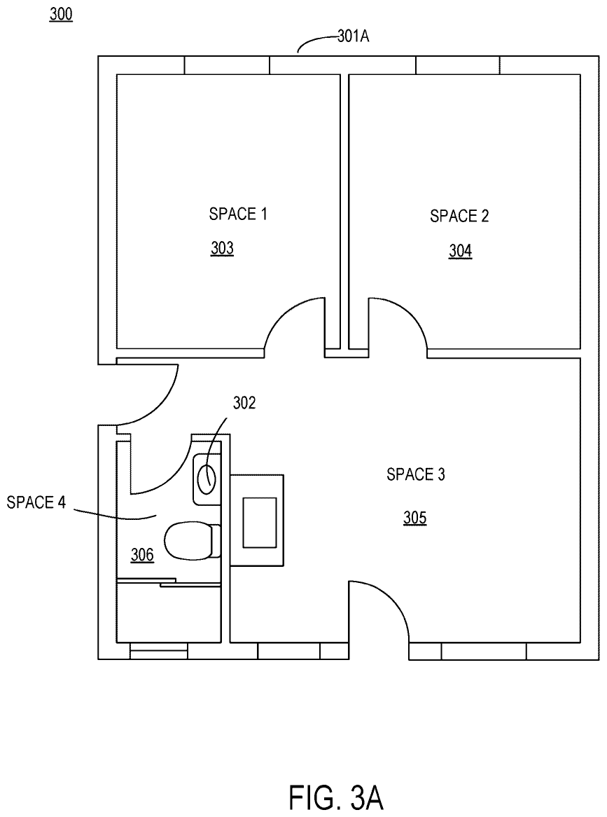

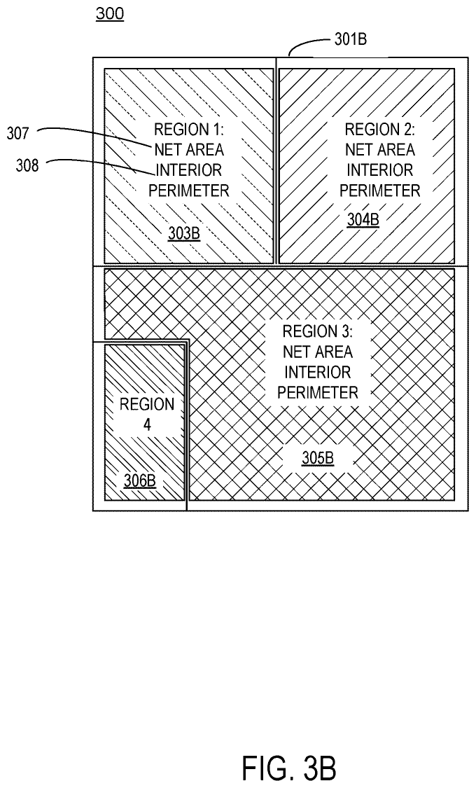

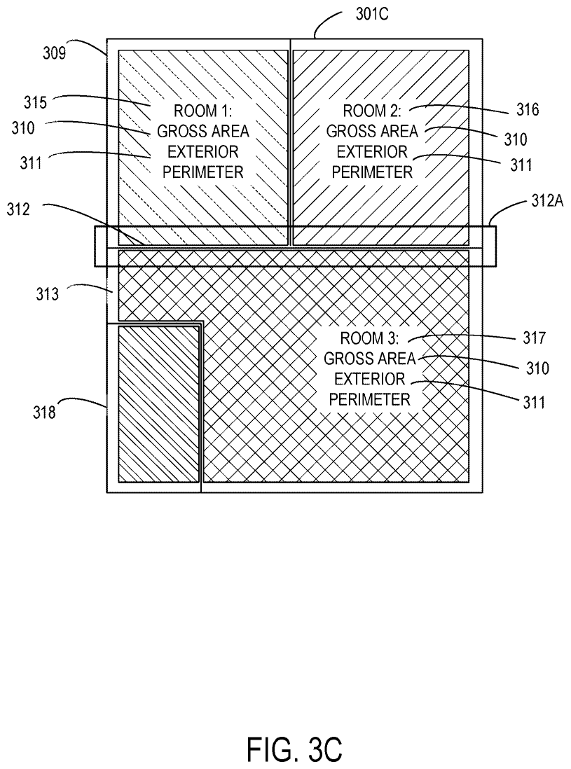

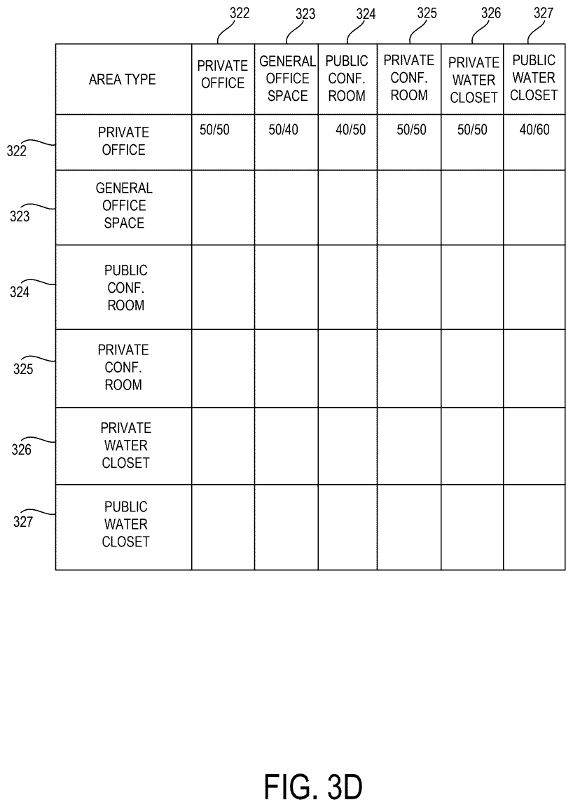

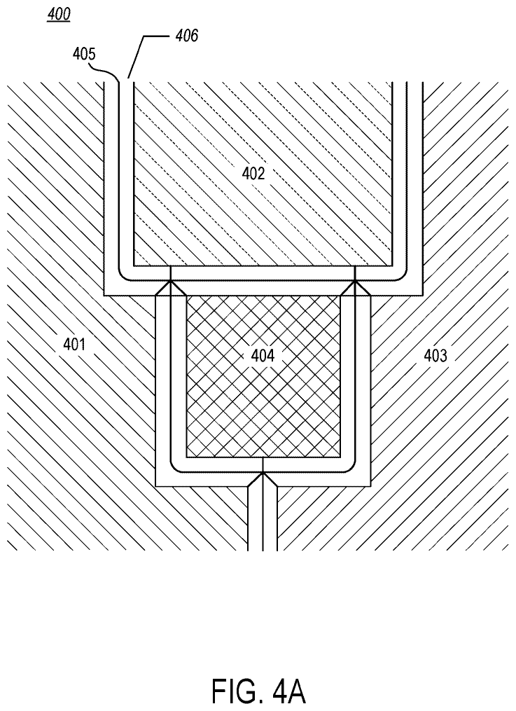

Referring now to FIGS. 3A-3C a user interface 300 may generate multiple different user views, each view has different aspects related to the two-dimensional reference drawing inputted. For example, referring now to FIG. 3A, a user interface 300 with a replication view 301A may include replication of an original floor plan represented by a two-dimensional reference, without any controller added features, vectors, lines, or polygons integrated or overlaid into the floorplan. The replication view 301A includes various spaces 303-306 that are undefined in the replication view 301A but may be defined during the processes described herein. For example, some or all of a space 303-306 may correlate to a region in a region view 301B.

The replication view 301A, may also include one or more fixtures 302. A rasterized version (or pixel version) of the fixtures 302 may be identified via an AI engine. If a pattern is present that is not identified as a fixture 302, a user may train the AI engine to recognize the pattern as a fixture of a particular type. The controller may generate a tally of multiple fixtures 302 identified in the two-dimensional reference. The tally of multiple fixtures 302 may include some or all of the fixtures identified in the two-dimensional reference and may be used to generate an estimate for completion of a project illustrated by, or otherwise represented by, the two-dimensional reference.

Referring now to FIG. 3B, in the user interface 300 a user may specify to a controller that one of multiple views available is to be presented via the interface. For example, a user may designate via an interactive portion of a screen displaying the user interface 300 that a region view 301B be presented. The region view 301B may identify one or more regions and/or spaces 303B-306B identified via processing by a controller, such as for example via an AI engine running on the controller. The region view 301B may include information about one or more regions 303-306 delineated in the region view 301B of the user interface 300. For example, the controller may automatically generate and/or display information descriptive of one or more of: user displays, printouts or summary reports showing a net interior area 307 (e.g., a calculation of square footage available to an occupant of a region), an interior perimeter 308, a type of use a region 303B-306B will be deployed for, or a particular material to be used in the region 303B-306B. For example, Region 4 306B may be designated for use as a bathroom; and flooring and wall board associated with Region 4 may be designated as needing to be waterproof material.

Referring now to FIG. 3C, a gross area region view 301C and 309 is illustrated. As illustrated in FIG. 3B, a user interface may include interactive devices for display of additional parameters, such as, for example, one or more of: a net interior area 307 may generate a designation of a value that is in contrast to a gross area 310 and exterior perimeter 311. The selection of gross area 310 may be more useful to a proprietor charging for a leased space, but may be less useful to an occupant than a net interior area 307 and interior perimeter 308. One or more of the net interior areas 307, interior perimeter 308 gross area 310 and exterior perimeter 311 may be calculated based upon analysis by an AI engine of a two-dimensional reference.

In addition, a height for a region may also be made available to the controller and/or an AI engine, then the controller may generate a net interior volume and vertical wall surface areas (interior and/or exterior).

In some embodiments, an output, such as a user interface of a computing device, smart device, tablet and the like, or a printout or other hardcopy, may illustrate one or both of: a gross area 310 and/or an exterior perimeter 311. Either output may include automatically populated information, such as the gross area of one or more rooms (based upon the above boundary computations) or exterior perimeters of one or more rooms.

In some embodiments, the present invention calculates an area bounded within a series of polygon elements (such as, for example, using mathematical principals or via pixel counting processes), and/or line segments.

In some embodiments, in an area of a bounded by lines intersecting at vertices, the vertices may be ordered such that they proceed in a single direction such as clockwise around the bounded area. The area may then be determined by cycling through the list of vertices and calculating an area between two points as the area of a rectangle between the lower coordinate point and an associated axis and the area of the triangle between the two points. When a path around the vertices reverses direction, the area calculations may be performed in the same manner, but the resulting area is subtracted from the total until the original vertex is reached. Other numerical methods may be employed to calculate areas, perimeters, volumes, and the like.

These views may be used in generating estimation analysis documents. Estimation analysis documents may rely on fixtures, region area, or other details. By assisting in generating net area, estimation documents may be generated more accurately and quickly than is possible through human-engendered estimation parameters.

With reference now again to FIGS. 3B and 3C, regions 303B-306B defined by an AI engine may include one or more Rooms in FIG. 3B subsequently have regions assigned as “Rooms” in FIG. 3C.

Referring now to FIG. 3D, a table is illustrated containing hierarchical relationships between area types 322-327 that may be defined in and/or by an AI engine and/or via the user interface. The area types 322-327 may be associated with dominance relationship values in relation to adjacent areas. For example, a border region 312-313 (as illustrated in FIG. 3C) will have an area associated with it. According to the present invention, an area 315-318 associated with the border region 312-313 may have an area type 322-327 associated with the area 315-318. An area 312A included in the border region 312-313 may be allocated according to a ratio based upon a dominance ranking of one feature as compared to another feature, which may be represented as a hierarchical relationship between the features, such as, for example adjacent areas (e.g., area 315 and area 317 or area 317 and area 318), the hierarchical relationship may be used to generate a dominance ranking of one area over another area, or to ascertain factors useful in determining whether a building is in alignment with environmental impact goals. For example, a dominance ranking may allocate space used to calculate one or more of: an occupancy load; a width and/or area of an egress path; a width and/or area of a common path; a length of a dead end; egress capacity; and travel distance from a furthest point. In certain embodiments, the dominance ranking imparts a significant influence on the alignment with environmental impact goals of design plans. In this context, regions assigned a higher dominance ranking are designated to be inherently associated with elevated safety standards. As a non-limiting example, these high-dominance regions are expected to undergo stringent scrutiny to ensure comprehensive alignment with environmental impact goals. The embodiment posits that regions carrying a higher dominance ranking may align with the stipulated environmental impact objectives, emphasizing an uncompromising commitment to safety. This approach underscores the pivotal role of the dominance ranking not only in guiding design revisions but also in prioritizing safety considerations, thereby fostering a meticulous and strategic approach to alignment with environmental impact goals within specific regions of the design plan.

Some embodiments of the present invention allocate one or more areas according to a user input (wherein the user input may be programmed to override and automated hierarchical relationship or be subservient to the automated hierarchical relationship). For example, as indicated in the table, a private office located adjacent to a private office may have an area in a border region split between the two adjacent areas in a 50/50 ratio, but a private office adjacent to a general office space may be allocated 60 percent of an area included in a border region, and so on.

Dominance associated with various areas or regions may be systemic throughout a project, according to customer preference, indicated on a two-dimensional reference by two-dimensional reference basis or another defined basis.

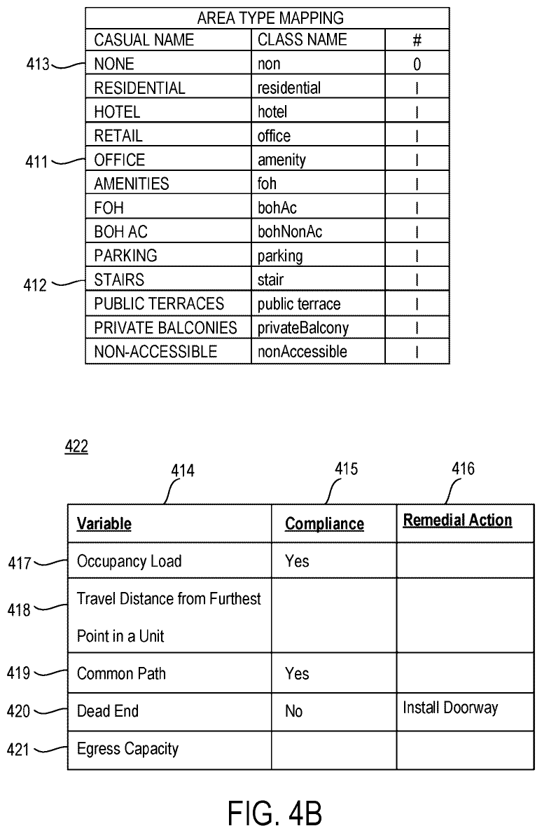

Referring now to FIG. 4A, an exemplary user interface 400 may include boundaries (which, as discussed above, may include one or more of: line segments, polygons, and icons) and regions overlaid on aspects included in a two-dimensional reference is illustrated. A defined space within a boundary (sometimes referred to as a region or area) may include an entire area within perimeters of a structure.

For example, a controller running an AI engine may determine locations of boundaries, edges, and inflections of neighboring and/or adjacent areas 401-404. There may be portions of boundary regions 405 and 406 that are initially not associated with an adjacent area 401-404. The controller may be operative via executing software in the AI engine to determine the nature of respective adjacent areas 401-404 on either side of a boundary, and apply a dominance-based ranking upon an area type, or an allocation of respective areas 401-404. Different classes or types of spaces or areas may be scored to be equal to, dominant (e.g., above) others or subservient (e.g., below) others.

Referring now to FIG. 4B, an exemplary table A indicating classes of space types and their associated ranks. In some embodiments, a controller may be operative via execution of software to determine relative ranks associated with a region on one or either side of a boundary. For example, area 402 may represent office space and area 404 may represent a stair well. An associated rank lookup value for office space may be found at rank 411, and the associated rank lookup value for stairwells may be found at rank 413. Since the rank 413 of stairwells may be higher, or dominant, over the rank 411 of office space then the boundary space may be associated with the dominant stairs 412 or stairwell space. In some embodiments, a dominant rank may be allocated to an entirety of boundary space at an interface region. In other examples, more complicated allocations may be made where the dominant rank may get a larger share of boundary space than another rank allocated by some functional relationship. In still other examples (Table B), controller may execute logical code to be operative to assign pre-established work costs to elements identified within boundaries.

In some embodiments, a boundary region may transition from one set of interface neighbors to a different set. For example, again in FIG. 4A, a boundary 405 between office region 402 and stairwell 404 may transition to a boundary region between office region 402 and unallocated space 403. The unallocated space may have a rank associated with the unallocated space 403 that is dominant. Accordingly, the nature of allocated boundary space 405 may change at such transitions where one space may receive allocation of boundary space in one pairing and not in a neighboring region. The allocation of the boundary space 405 may support numerous downstream functionalities and provide an input to various application programs. Summary reports may be generated and/or included in an interface based upon a result after incorporation of assignment of boundary areas.

In another aspect, in FIG. 4B, a table 422 illustrates fields 414-416 that may have variable 417-421 values designated by an AI engine or other process run by a controller based upon the two-dimensional reference, such as a floor plan, design plan or architectural blueprint. The variables 417-421 include aspects that may affect alignment with environmental impact goals with conditions that may be met in order to be adherent with an environmental impact objective, such as, for example, alignment with environmental impact goals and remedial actions.

### Area Takeoff Classification

The determination of boundary definitions for a given inputted design plan, which may be a single drawing or set of drawings or other image, has many important uses and aspects as has been described. However, it can also be important for a supporting process executed by a controller, such as an AI algorithm to take boundary definitions and area definitions and generate classifications of a space. As mentioned, this can be important to support processes executed by a controller that assigns boundary areas based on dominance of these classifications.

Classification of areas can also be important for further aggregations of space. In a non-limiting example, accurate automatic classification of room spaces may allow for a combination of all interior spaces to be made and presented to a user. Overlays and boundary displays can accordingly be displayed for such aggregations. There may be numerous functionalities and purposes for automatic classification of regions from an input drawing.

An AI engine or other process executed by a controller may be refined, trained, or otherwise instructed to utilize a number of recognized characteristics to accomplish area classification. For example, an AI engine may base predictions for a type “/”category” of a region with a starting point of the determination that a region exists from the previous predictions by the segmentation engine.

In some embodiments, a type may be inferred from text located on an input drawing or other two-dimensional reference. An AI engine may utilize a combination of factors to classify a region, but it may be clear that the context of recognized text may provide direct evidence upon which to infer a decision. For example, a recognized textual comment in a region may directly identify the space as a bedroom, which may allow the AI engine to make a set of hierarchical assignments to space and neighboring spaces, such as adjoining bathrooms, closets, and the like.

Classification may also be influenced by, and use, a geometric shape of a predicted region. Common shapes of certain spaces may allow a training set to train a relevant AI engine to classify a space with added accuracy. Furthermore, certain space classes may typically fall into ranges of areas which also may aid in the identification of a region's class. Accordingly, it may be important to influence the makeup of training sets for classification that contain common examples of various classes as well as common variations on that theme.

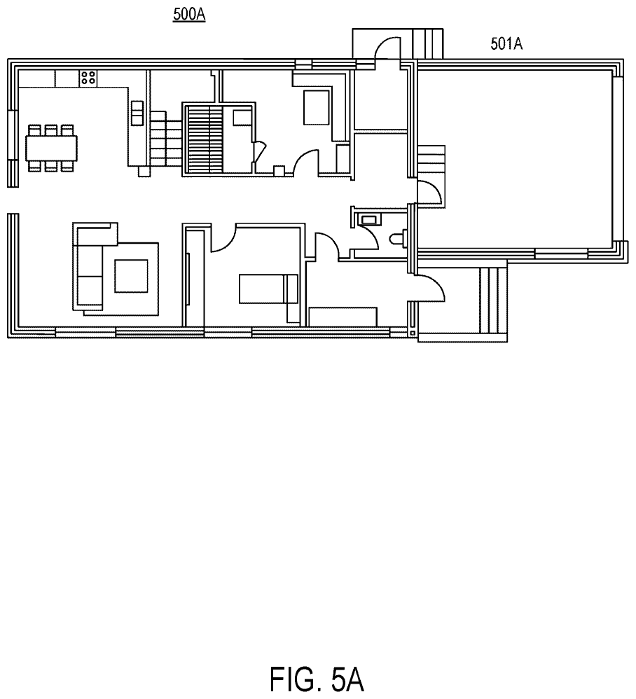

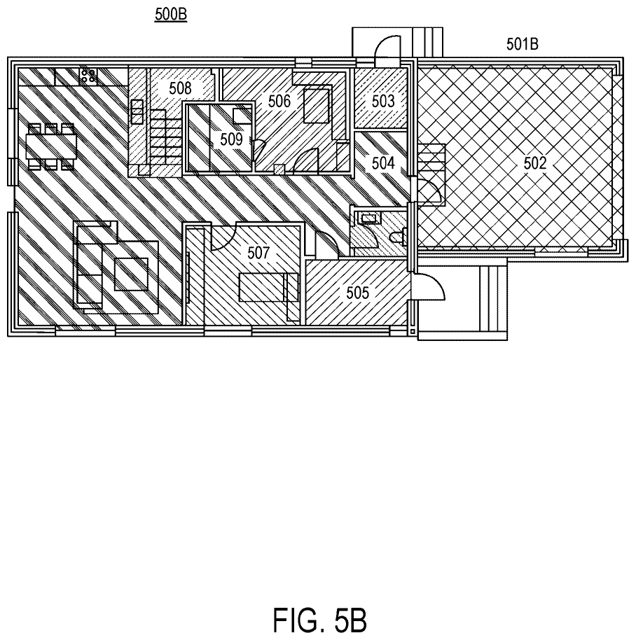

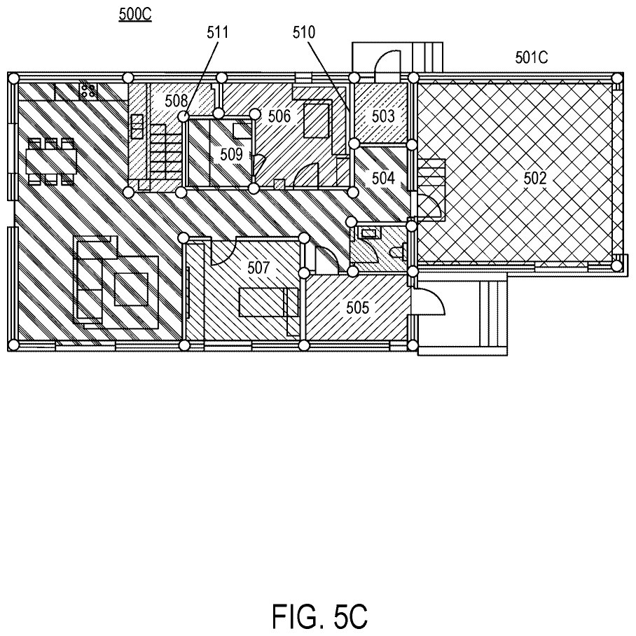

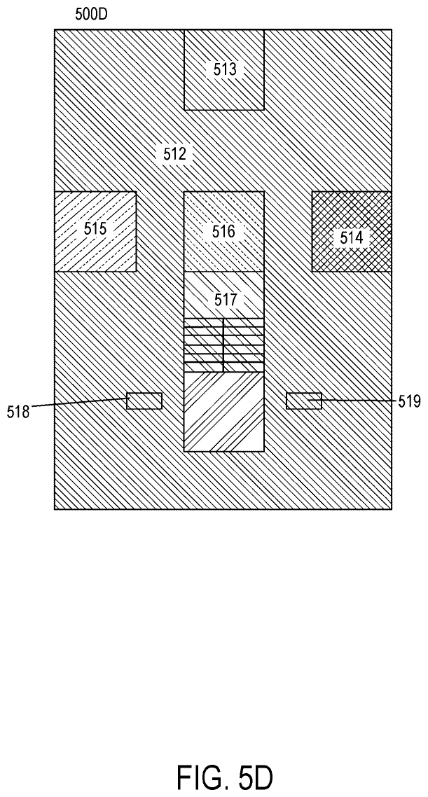

Referring now to FIGS. 5A-5D, a progressive series of outputs that may be included in various user interfaces are illustrated and provide examples of a recognition process that may be implemented in some embodiments of the present invention. Referring now to FIG. 5A, a relatively complex drawing of a floorplan may be input as a design plan 501A into a controller running an AI engine. The two-dimensional reference 501 may be included in an initial user interface 500A.

An AI engine based automated recognition process executes method steps via a controller, such as a cloud server, and identifies multiple disparate regions 502-509. Designation of the regions 502-509 may be integrated according to a shape and scale of the two-dimensional reference and presented as a region view 501B user interface 500B, with symbolic hatches or colors etc., as shown in FIG. 5B.

The region view 501B may include the multiple regions 502-509 identified by the AI engine arranged based upon to a size and shape and relative position derived from the two-dimensional reference 501.

Referring now to FIG. 5C, a line segment view 501C may include identified boundary line segments 510 and vertices 511 may also be presented as an overlay of the regions 502-509 illustrated as delineated symbolic hatches or colors etc., as illustrated in FIG. 5C. Said line segments 510 may also be represented as symbols such as but not limited to dots. Such an interactive user interface 500C may allow a user to review and correct assignments in some cases. A component of the AI engine may further be trained to recognize aggregations of regions 502-509 spaces, or areas, such as in a non-limiting sense the aggregation of internal regions 502-509, spaces or areas.

Referring now to FIG. 5D, an illustration of exemplary aggregation of regions 512-519 is provided where a user interface 500D includes patterned portions 512-519 and the patterned portions 512-519 may be representative of regions, spaces, or areas, such as, for example, aggregated interior living spaces.

In some embodiments, integrated and/or overlaid aggregations of some or all of regions; spaces; patterned portions; line segments; polygons; symbols; icons or other portions of the user interfaces may be assembled and presented in a user output and our user interface, or as input into another automated process.

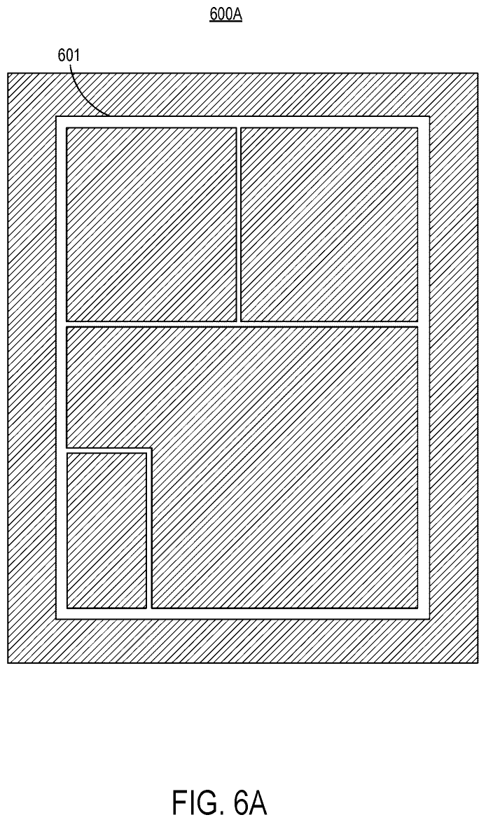

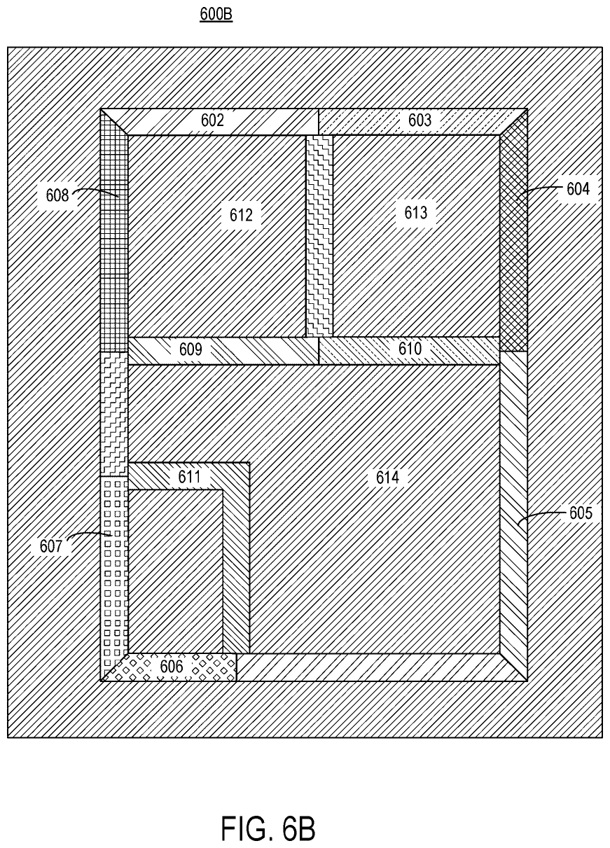

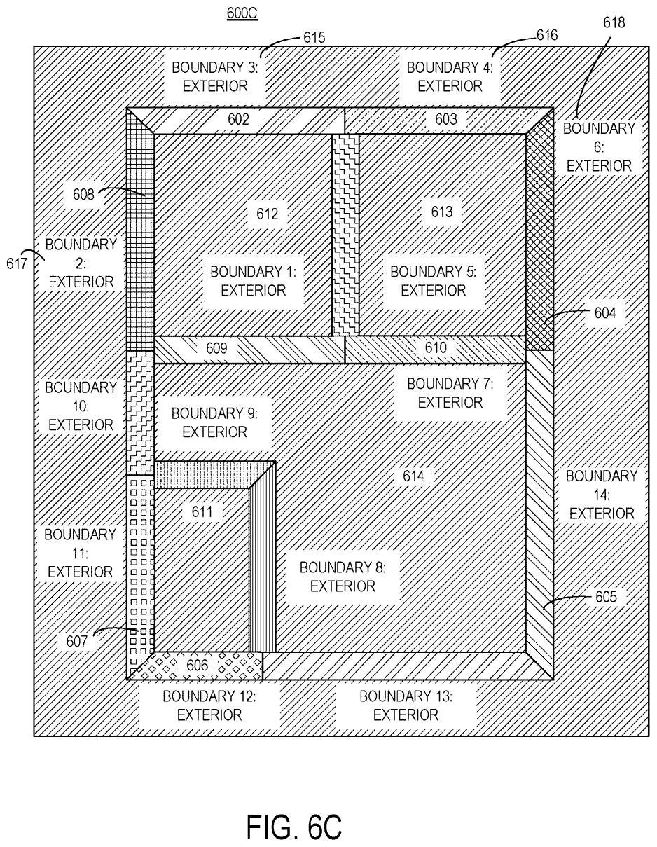

Referring now to FIGS. 6A-6C, in some embodiments, automated and/or user-initiated processes may include refinement of regions, spaces, or areas may involve one or both of a user and a controller identifying individual wall segments 211A from previously defined boundaries.

For example, in some embodiments, a controller running an AI engine may execute processes that are operative to divide a previously predicted boundary into individual wall segments. In FIG. 6A, a user interface 600A includes a representation of a design plan with an original boundary 601 defined from an inputted design.

In FIG. 6B, an AI engine may be operative to take one or more original boundaries 601 and isolate one or more individual line segments 602-611 as shown by different hatching symbols in an illustrated user interface 600B. The identification of individual line segments 602-611 of a boundary 601 enables one or both of a controller and a user to assign and/or retrieve information about the individual line segment 602-611 such as, for example, one or more of: the length of the segment 602-611, a type of wall segment 211A, materials used in the wall segment 211A, parameters of the segment 602-611, height of the segment 602-611, width of the segment 602-611, allocation of the segment 602-611 to a region 612-614 or another, and almost any digital content relevant to the segment.

Referring now to FIG. 6C, in some embodiments, a controller executing an AI engine or other method steps, may be operative, in some embodiments, to classify individual line segments 602-611 of a boundary 601 and present a user interface 600C indicating the classified individual line segments 602-611. The AI engine may be trained, and subsequently operative, to classify individual line segments 602-611 included in a boundary 601 in different classes. As a non-limiting example, an AI engine may classify walls as interior walls, exterior walls and/or demising walls that separate internal spaces.

As illustrated in FIG. 6C, in some embodiments, an individual line segment 602-611 may be classified by the AI engine and an indication of the classification 615-618, such as alphanumeric or symbolic content, may be associated with the individual line segment 602-611 and presented in the user interface 600C.

In some embodiments, functionality may be allocated to classified individual line segments 602-611, such as, by way of non-limiting example, a process that generates an estimated materials list for a region or an area defined by a boundary, based on the regions or area's characteristics and its classification.

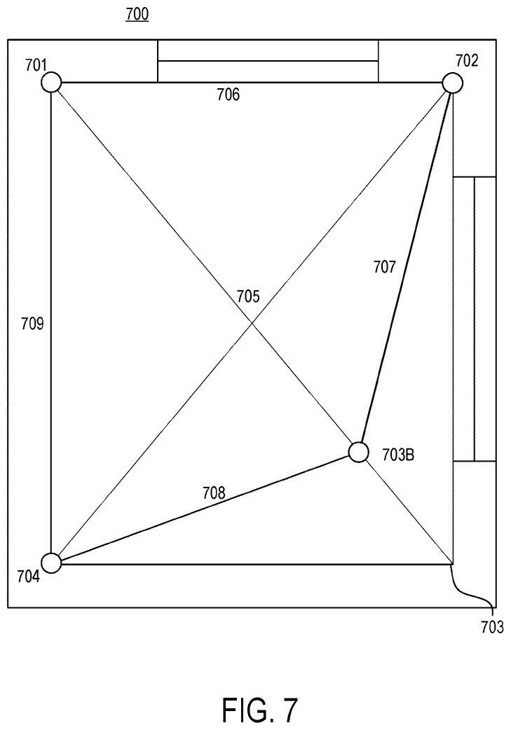

Referring now to FIG. 7 in some embodiments, a user interface 700 may include user interactive controls operative to execute process steps described herein (e.g. make a boundary determination, region classification, segmentation decision or the like) in an automated process (e.g. via an AI routine) and also be able to receive an instruction (e.g. from a user via a user interface, or a controller operative via executable software to perform a process) that modify one or more boundary segments.

For example, a user interface may include one or more vertex 701-704 (e.g., points where two or more line segments meet) that may be user interactive such that a user may position the one or more vertex 701-704 at a user selected position. User positioning may include, for example, user drag and drop of the one or more vertex 701-704 at a desired location or entering a desired position, such as via coordinates. A new position for a vertex 703B may allow an area 705 bounded by user defined boundaries 706-709 User interactive portions of a user interface 700 are not limited to vertex 701-704 and can be any other item 701-709 in the user interface 700 that may facilitate achievement of a purpose by allowing one or both of: the user, and the controller, to control dynamic sizing and/or placement of a feature or other item 701-709.

Still further, in some embodiments, user interaction involving positioning of a vertex 701-704 or modification of an item 705-709 may be used to train an AI engine to improve performance.

### Model Training Procedures

An important aspect of the operation of the systems as have been described is the training of the AI engines that perform the functions as have been defined. A training dataset may involve a set of input drawings associated with a corresponding set of verified outputs. In some embodiments, a historical database of drawings may be analyzed by personnel with expertise in the field. user, including in some embodiments experts in a particular field of endeavor may manipulate dynamic features of a design plan or other aspects of a user interface to be used to train an AI engine, such as by creating or adding to an AI referenced database.

In some other examples, a trained version of an AI engine may produce user interfaces and/or other outputs based on the trained version of the AI engine. Teams of experts may review the results of the AI processing and make corrections as required. Corrected drawings may be provided to the AI engine for renewed training.

### Estimation Automation

Aspects that are determined by a controller running an AI engine to be represented in a design plan may be used to generate an estimate of what will be required to complete a project. For example, according to various embodiments of the present invention, an AI engine may receive as input a two-dimensional reference and generate one or more of: boundaries, areas, fixtures, architectural components, perimeters, linear lengths, distances, volumes, and the like may be determined by a controller running an AI engine to be required to be required to complete a project.

For example, a derived area or region comprising a room and/or a boundary, perimeter or other beginning and end indicator may allow for a building estimate that may integrate choices of materials with associated raw materials costs and with labor estimates all scaled with the derived parameters. The boundary determination function may be integrated with other standard construction estimation software and feed its calculated parameters through APIs. In other examples, the boundary determination function may be supplemented with the equivalent functions of construction estimation to directly provide parametric input to an estimation function. For example, the parameters derived by the boundary determinations may result in estimation of needed quantities like cement, lumber, steel, wall board, floor treatments, carpeting, and the like. Associated labor estimates may also be calculated.

As described herein, a controller executing an AI engine may be functional to perform pattern recognition and recognize features or other aspects that are present within an input two-dimensional reference or other graphic design. In a segmentation phase used to determine boundaries of regions or other space features, aspects that are recognized as some artifact other than a boundary may be replaced or deleted from the image. An AI engine and/or user modified resulting boundary determination can be used in additional pattern recognition processing to facilitate accurate recognition of the non-wall features present in the graphic.

For example, in some embodiments, a set of architectural drawings may include many elements depicted such as, by way of non-limiting example, one or more of: windows, exterior doors, interior doors, hallways, elevators, stairs, electrical outlets, wiring paths, floor treatments, lighting, appliances, and the like. In some two-dimensional references, furniture, desks, beds, and the like may be depicted in designated spaces. AI pattern recognition capabilities can also be trained to recognize each of these features and many other such features commonly included in design drawings. In some embodiments, a list of all the recognized image features may be created and also used in the cost estimation protocols as have been described.

In some embodiments of the present invention, a recognized feature may be accompanied on a drawing with textual description which may also be recognized by the AI image recognition capabilities. The textual description may be assessed in the context of the recognized physical features in its proximity and used to supplement the feature identification. Identified feature elements may be compared to a database of feature elements, and matched elements may be married to the location on the architectural plan. In some embodiments, text associated with dimensioning features may be used to refine the identity of a feature. For example, a feature may be identified as an exterior window, but an association of a dimension feature may allow for a specific window type to be recognized. Additionally, a text input or other narrative may be recognized to provide more specific identification of a window type.

Identified features may be associated with a specific item within a features database. The item within the features database may have associated records that precisely define a vector graphics representation of the element. Therefore, an input graphic design may be reconstituted within the system to locate wall and other boundary elements and then to superimpose a database element graphic associated with the recognized feature. In some embodiments, various feature types and text may be associated into separate layers of a processed architectural design. Thus, a user interface or other output display or on reports, different layers may be illustrated at different times along with associated display of estimation results.

In some embodiments, a drawing may be geolocated by user entry of data associated with the location of a project associated with the input architectural plans. The calculations of raw material, labor and the like may then be adjusted for prevailing conditions in the selected geographic location. Similarly, the geolocation of the drawing may drive additional functionality. The databases associated with the systems may associate a geolocation with an environmental impact objective, standards and the like and review the discovered design elements for alignment with environmental impact goals. In some embodiments, a list of variances or discovered potential issues may be presented to a user on a display or in a report form. In some embodiments, a function may be offered to remove user entered data and other personally identifiable information associated in the database with a processing of a graphic image.

In some embodiments, a feature determination that is presented to a user in a user interface may be assessed as erroneous in some way by the user. The user interface may include functionality to allow the user to correct the error. The resulting error determination may be included in a training database for the AI engine to help improve its accuracy and functionality.

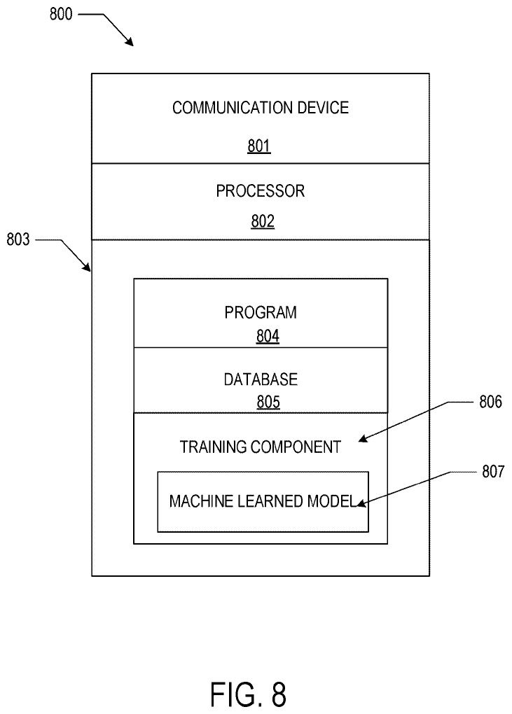

Referring now to FIG. 8, an automated controller is illustrated, which may be used to implement various aspects of the present disclosure, in various embodiments, and for various aspects of the present disclosure, controller 800 may be included in one or more of: a wireless tablet or handheld device, a server, a rack mounted processor unit. The controller may be included in one or more of the apparatuses described above, such as a Server, and a Network Access Device. The controller 800 includes a processor unit 802, such as one or more semiconductor-based processors, coupled to a communication device 801 configured to communicate via a communication network (not shown in FIG. 8). The communication device 801 may be used to communicate, for example, with one or more online devices, such as a personal computer, laptop, or a handheld device.

The processor 802 is also in communication with a storage device 803. The storage device 803 may comprise any appropriate information storage device, including combinations of magnetic storage devices (e.g., magnetic tape and hard disk drives), optical storage devices, and/or semiconductor memory devices such as Random Access Memory (RAM) devices and Read Only Memory (ROM) devices.

The storage device 803 can store a software program 804 with executable logic for controlling the processor 802. The processor 802 performs instructions of the software program 804, and thereby operates in accordance with the present disclosure. In some embodiments, the processor may be supplemented with a specialized processor for AI related processing. The processor 802 may also cause the communication device 801 to transmit information, including, in some instances, control commands to operate apparatus to implement the processes described above. The storage device 803 can additionally store related data in a database 805. The processor and storage devices may access an AI training component 806 and database, as needed which may also include storage of machine learned models 807.

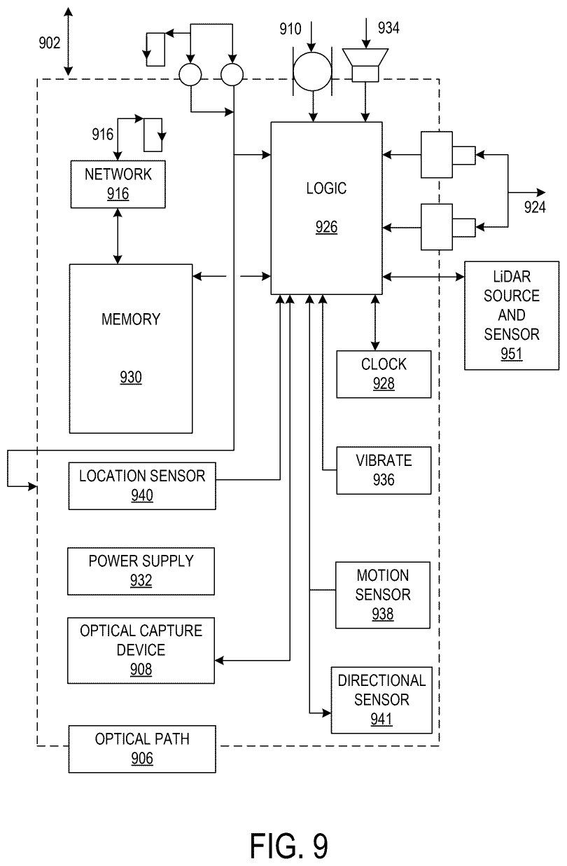

Referring now to FIG. 9, a block diagram of an exemplary mobile device 902 is illustrated. The mobile device 902 comprises an optical capture device 908 to capture an image and convert it to machine-compatible data, and an optical path 906, typically a lens, an aperture, or an image conduit to convey the image from the rendered document to the optical capture device 908. The optical capture device 908 may incorporate a Charge-Coupled Device (CCD), a Complementary Metal Oxide Semiconductor (CMOS) imaging device, or an optical Sensor 924 of another type.

A microphone 910 and associated circuitry may convert the sound of the environment, including spoken words, into machine-compatible signals. Input facilities may exist in the form of buttons, scroll wheels, or other tactile Sensors such as touchpads. In some embodiments, input facilities may include a touchscreen display.

Visual feedback to the user is possible through a visual display, touchscreen display, or indicator lights. Audible feedback 934 may come from a loudspeaker or other audio transducer. Tactile feedback may come from a vibrate module 936.

A motion Sensor 938 and associated circuitry convert the motion of the mobile device 902 into machine-compatible signals. The motion Sensor 938 may comprise an accelerometer that may be used to sense measurable physical acceleration, orientation, vibration, and other movements. In some embodiments, motion Sensor 938 may include a gyroscope or other device to sense different motions.

A location Sensor 940 and associated circuitry may be used to determine the location of the device. The location Sensor 940 may detect Global Position System (GPS) radio signals from satellites or may also use assisted GPS where the mobile device may use a cellular network to decrease the time necessary to determine location.

The mobile device 902 comprises logic 926 to interact with the various other components, possibly processing the received signals into different formats and/or interpretations. Logic 926 may be operable to read and write data and program instructions stored in associated storage or memory 930 such as RAM, ROM, flash, or other suitable memory. It may read a time signal from the clock unit 928. In some embodiments, the mobile device 902 may have an on-board power supply 932. In other embodiments, the mobile device 902 may be powered from a tethered connection to another device, such as a Universal Serial Bus (USB) connection.

The mobile device 902 also includes a network interface 916 to communicate data to a network and/or an associated computing device. Network interface 916 may provide two-way data communication. For example, network interface 916 may operate according to the internet protocol. As another example, network interface 916 may be a local area network (LAN) card allowing a data communication connection to a compatible LAN. As another example, network interface 916 may be a cellular antenna and associated circuitry which may allow the mobile device to communicate over standard wireless data communication networks. In some implementations, network interface 916 may include a Universal Serial Bus (USB) to supply power or transmit data. In some embodiments other wireless links may also be implemented.

As an example of one use of mobile device 902, a reader may scan an input drawing with the mobile device 902. In some embodiments, the scan may include a bit-mapped image via the optical capture device 908. Logic 926 causes the bit-mapped image to be stored in memory 930 with an associated timestamp read from the clock unit 928. Logic 926 may also perform optical character recognition (OCR) or other post-scan processing on the bit-mapped image to convert it to text.

A directional sensor 941 may also be incorporated into the mobile device 902. The directional device may be a compass and be based upon a magnetic reading or based upon network settings.

A LiDAR sensing system 951 may also be incorporated into the mobile device 902. The LiDAR system may include a scannable laser light (or other collimated) light source which may operate at nonvisible wavelengths such as in the infrared. An associated sensor device, sensitive to the light of emission may be included in the system to record time and strength of returned signal that is reflected off of surfaces in the environment of the mobile device 902. In some embodiments, as have been described herein, a 2 dimensional drawing or representation may be used as the input data source and, vector representations in various forms may be utilized as a fundamental or alternative input data source. Moreover, in some embodiments, files which may be classified as BIM input files may be directly used as a source on which method steps may be performed. BIM and CAD file formats may include, by way of non-limiting example, one or more of: BIM, RVT, NWD, DWG, IFC and COBie. Features in the BIM or CAD datafile may already have defined boundary aspects having innate definitions such as walls and ceilings and the like. An interactive interface may be generated that receives input from a user indicating a user choice of types of innate boundary aspects a user provides instruction to the controller to perform subsequent processing on.

In some embodiments, a controller may receive user input enabling input data from either a design plan format or similar such formats, or also allow the user to access BIM or CAD formats. Artificial intelligence may be used to assess boundaries in different manners depending on the type of input data that is initially inputted. Subsequently, similar processing may be performed to segment defined spaces in useable manners as have been discussed. The segmented spaces may also be processed to determine classifications of the spaces.

As has been described, a system may operate (and AI Training aspects may be focused upon) recognition of lines or vectors as a basic element within an input design plan. However, in some embodiments, other elements may be used as a fundamental element, such as, for example, a polygon and/or series of polygons. The one or more polygons may be assembled to define an area with a boundary, as compared, in some embodiments, with an assembly of line segments or vectors, which together may define a boundary which may be used to define an area. Polygons may include different vertices; however common examples may include triangular facets and quadrilateral polygons. In some embodiments, AI training may be carried out with a singular type of polygonal primitive element (e.g., rectangles), other embodiments will use a more sophisticated model. In some other examples, AI engine training may involve characterizing spaces where the algorithms are allowed to access multiple diverse types of polygons simultaneously. In some embodiments, a system may be allowed to represent boundary conditions as combinations of both polygons and line elements or vectors.

Depending upon one or more factors, such as processing time, a complexity of the feature spaces defined, and a purpose for AI analysis, simplification protocols may be performed as have been described herein. In some embodiments, object recognition, space definition or general simplification may be aided by various object recognition algorithms. In some embodiments, Hough type algorithms may be used to extract diverse types of features from a representation of a space. In other examples, Watershed algorithms may be useful to infer division boundaries between segmented spaces. Other feature recognition algorithms may be useful in determining boundary definitions from building drawings or representations.

### User Interface With Single and Multiple Layers

In some embodiments, the user may be given access to movement of boundary elements and vertices of boundary elements. In examples where lines or vectors are used to represent boundaries and surrounding areas, a user may move vertices between lines or center points of lines (which may move multiple vertices). In other examples, elements of polygons such as the user may move vertices, sides, and center points. In some embodiments, the determined elements of the space representation may be bundled together in a single layer. In other examples, multiple layers may be used to distinguish distinct aspects. For example, one layer may include the AI optimized boundary elements, another layer may represent area and segmentation aspects, and still another layer may include object elements. In some embodiments, when the user moves an element such as a vertex the effects may be limited only to elements within its own layer. In some examples, a user may elect to move multiple or all layers in an equivalent manner. In still further examples, all elements may be assigned to a single layer and treated equivalently. In some embodiments, users may be given multiple menu options to select disparate elements for processing and adjustment. Features of elements such as color and shading and stylizing aspects may be user selectable. A user may be presented with a user interface that includes dynamic representations of a features or other aspects of a design plan, and associated values and changes may be input by a user. In some embodiments, an algorithm and processor may present to the user comparisons of various aspects within a single model or between different models. Accordingly, in various embodiments, a controller and a user may manipulate aspects of a user interface and AI engine.

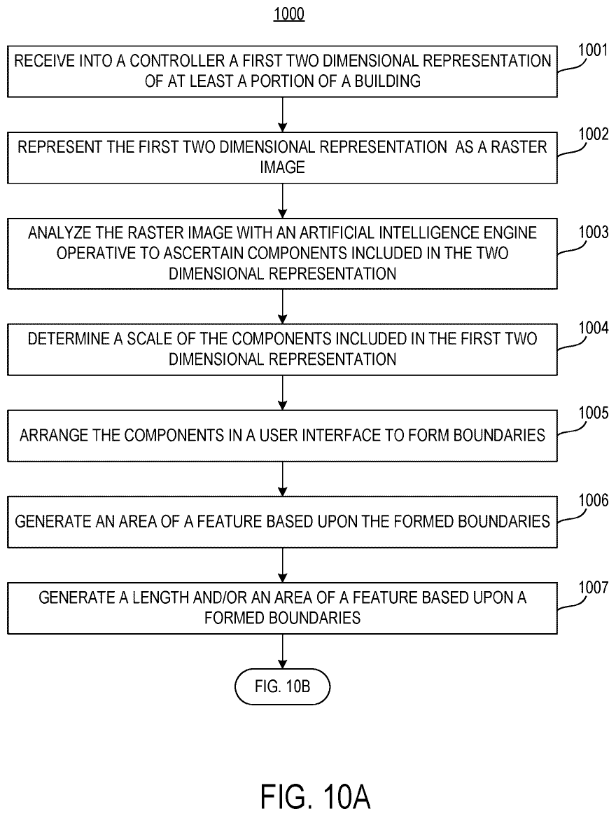

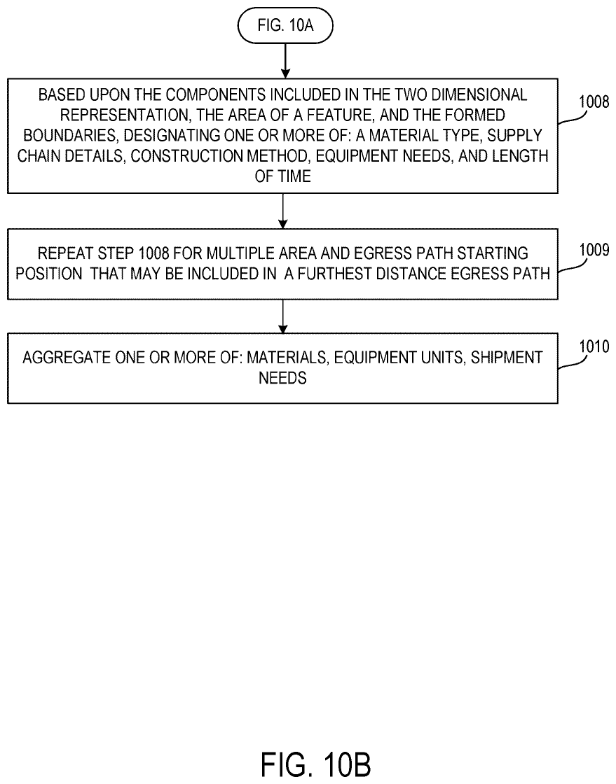

Referring now to FIGS. 10A-10B method steps are illustrated for quantifying requirements for alignment with environmental impact goals applied to a building based upon artificial intelligence analysis of a design plan according to some embodiments of the present invention. At step 1001, the method includes receiving into a controller a design plan (or a first two-dimensional representation) of at least a portion of a building. As described above, the design plan may include an architectural drawing, floor plan, design drawing and the like.

At step 1002, the portion of a design plan (or a first two-dimensional representation) may be represented as a raster image or other image type that is conducive to artificial intelligence analysis, such as, for example, a pixel-based drawing.

At step 1003, the raster image may be analyzed with an artificial intelligence engine that is operative on a controller to ascertain components included in the design plan.

At step 1004, a scale of components included in the design plan may be determined. The scale may be determined, for example, via a scale indicator or ruler included in the design plan, or inclusion in the design plan of a component of a known dimension.

At step 1005, a user interface may be generated that includes at least some of the multiple components.

At step 1006, the components may be arranged in the user interface to form boundaries.

At step 1007, a length of a feature may be generated based upon a formed boundary.

At step 1008, based upon one or more of components included in at least one of: the user interface and the design plan, at least one of: the area of a feature, space or region may be generated and/or a length of a feature may be generated and one or more of: a material type, supply chain details (e.g. a length of travel from a source to a construction site, transport type, etc.); construction method, equipment needs, and length of construction process.

At step 1009, one or more of the above steps may be repeated for multiple areas, units and structure types included in a building being described by the design plan.

At step 1010, values of variables specified in a relevant environmental impact objective may be aggregated. The aggregated quantities may include, by way of non-limiting example, one or more of: material types and quantities; equipment units, and shipment needs.

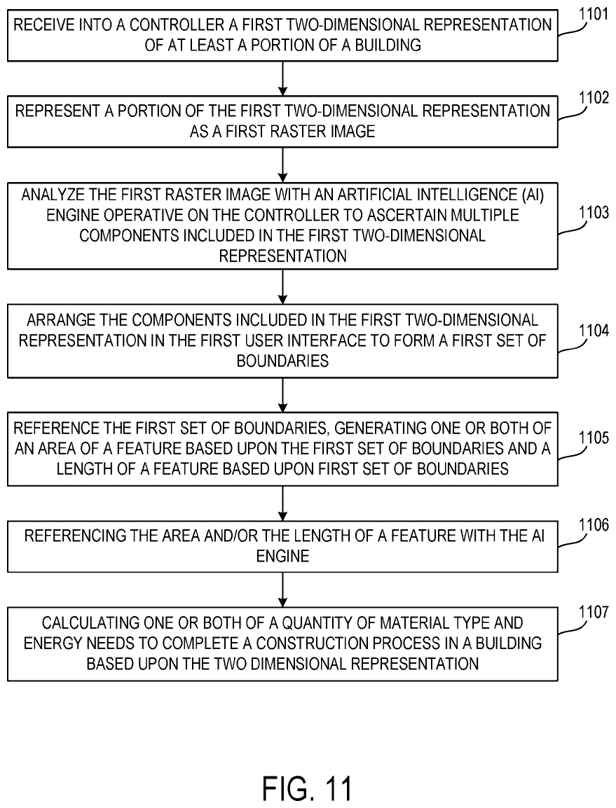

Referring now to FIG. 11, a system including one or more controllers can be configured to perform particular operations or actions by virtue of having executable software, firmware, hardware, or a combination of them that in operation cause the controllers to be operative to perform method steps. In some embodiments, the controller may perform method steps directed to quantifying requirements (e.g., alignment with environmental impact goals) for construction of a building based upon artificial intelligence analysis of design plans.

At step 1101, the method of quantifying whether requirements for alignment with environmental impact goals are present in a building may include receiving into a controller a first design plan (or a first two-dimensional representation) of at least a portion of a building.

At step 1102 the method may include representing a portion of the first design plan as a first raster image; and step 1103 analyzing the first raster image with an artificial intelligence (AI) engine operative on the controller to ascertain multiple components included in the first design plan. The controller may also generate a first user interface including at least some of the multiple components included in the first design plan; and at step 1104, arrange the components included in the first design plan in a first user interface that forms a first set of boundaries.

At step 1105, the method may include generating one or both of an area of a feature based upon the first set of boundaries and a length of a feature based upon first set of boundaries.

At step 1106, the method may include using the AI engine to reference at least one of: the area of the feature and the length of a feature, and at step 1107 the controller may calculate one or more of: a quantity of material, a type of material, and energy needs to complete a construction process.

Any or all of steps 1101-1107 may be repeated for different portions of the two-dimensional reference descriptive of the building. For example, for a second design plan representing a different portion of the entire building design.

A scale of one or more components may be determined and a parameter of one or both of a polygon and a line segment may be modified based upon receipt of an instruction from a user; and a boundary may be set based upon reference to a boundary allocation hierarchy.

The steps may be performed multiple times and may include two or more two dimensional references (design plans) with results of the process be compared one against the other to ascertain when a change has been made to a two-dimensional reference that places a building in alignment with environmental impact goals. In various embodiments, a change in subsequent two-dimensional references may be used to generate a change in one or more of a take off, labor costs, project management input, or other aspects that may impact construction of a building, and/or associated costs.

Implementations may include one or more of the following features. The method additionally comprises determining a scale of the components included in the design plan and/or generating a user interface including user interactive areas to change at least one of: a size and shape of at least one of the dynamic components, the dynamic components may include, by way of non-limiting example, one or more of: architectural features, polygons or arcuate shapes; regions, areas, spaces, travel paths, egress paths, dominance hierarchies, occupancy loads, doorways, stairs, or other portion of a design plan that may be modified.

In some embodiments dynamic components may include a polygon and/or arcuate shape. A method of practice of the present invention may further include the steps of: receiving an instruction via the user interactive interface to modify a parameter of the polygon and modifying the parameter of the polygon based upon the instruction received via the interactive user interface. The parameter modified may include one or both of: an area of the polygon; and a shape of the polygon.

In another aspect a dynamic component may include a line segment and/or arcuate segment, and methods of practice may include one or more of: receiving an instruction via a user interactive interface to modify a parameter of the line segment, and the method further includes the step of modifying the parameter of the line segment based upon the instruction received via the interactive user interface. The parameter of the line segment may include a length of the line segment, and the method may additionally include modifying a length of a wall based upon the modifying the length of the line segment.

The parameter modified may additionally include a direction of the line segment and the method may additionally include modifying an area of a room based upon the modifying of the length and direction of the line segment. A boundary may be set based upon reference to a boundary allocation hierarchy.

In another aspect, a price may be associated with each of the quantities of items to be included in construction of the building. In addition, a type of labor associated with at least one of the items to be included in construction of the building may be designated based upon AI analysis of the first two-dimensional reference (i.e., first design plan) and the second two-dimensional reference (i.e., second design plan), respectively.

Methods of practice may additionally include the steps of: determining whether a design plan received into the controller includes a vector image, and if one of the first and the second design plan received into the controller includes a vector image, converting at least a portion of the vector image into a raster image. Implementations of the described techniques may include hardware, a method or process, or computer software on a computer-accessible medium.

Methods of practice may additionally include one or more of the steps of: generating a user interface including user interactive areas to change at least one of: a size and shape of at least one of the dynamic components. At least one of the dynamic components may include a polygon and the method further includes the steps of: receiving an instruction via the user interactive interface to modify a parameter of the polygon and modifying the parameter of the polygon based upon the instruction received via the interactive user interface. The parameter modified may include an area of the polygon and/or a shape of the polygon. Moreover, a modification of a dynamic component included in a polygon may change a calculation of an area of a unit (e.g., room or a portion of a building), or other defined space. A change in area of a unit may allow for a recalculation that results in a modification of one or more of: a material type, a quantity of material; energy required to install the material; energy required to transport a material to a job site; or other variable referenced in determination of alignment with environmental impact goals, such as a carbon impact goals relevant to a geopolitical locality and a building.

A dynamic component may include a line segment and/or vector, and the method may further include the steps of: receiving an instruction via the user interactive interface to modify a parameter of the line segment and/or vector and modifying the parameter of the line segment and/or vector based upon the instruction received via the interactive user interface. The parameter modified may include a magnitude of the line segment and/or vector and/or a direction of the vector.

The methods may additionally include one or more of the steps of setting a boundary based upon reference to a boundary allocation hierarchy; associating a price with each of the quantities of items to be included construction of the building; totaling the aggregated prices of items to be included construction of the building; designating a type of labor associated with at least one of the items to be included construction of the building; designating a quantity of the type of labor associated with the at least one of the items to be included in construction of the building; repeating the steps of designating a type of labor associated with at least one of the items to be included construction of the building and designating a quantity of the type of labor associated with the at least one of the items to be included in construction of the building for multiple items, and generating an aggregate quantity of the type of labor (e.g., based upon modification in a design plan for alignment with environmental impact goals).

The method may additionally include the step of training the AI engine based upon a human identifying portions of a design plan to indicate that it includes a particular type of item; or to identify portions of the design plan that include a boundary. The AI engine via may also be trained by reference to a boundary allocation hierarchy.

The methods may additionally include the steps of: determining whether the design plans received into the controller includes a vector image, and if the design plan received into the controller does include a vector image converting at least a portion of the vector image into a raster image; and/or whether a design plan includes a vector image format. Implementations of the described techniques and method steps may include hardware (such as a controller and/or computer server), a method or process, or computer software on a computer-accessible medium.

In some embodiments, a novel approach may include ensuring alignment with environmental impact goals with deployment objectives in architectural design plans. By incorporating a sophisticated algorithm and/or the AI engine, these embodiments may enable a meticulous comparison between the allowable distance of the path of egress and the calculated distances of all potential egress paths within a given design plan.

Via seamless integration of the AI engine, the technology not only identifies potential discrepancies but also proposes optimized automated solutions or revisions to enhance the overall safety or alignment with environmental impact goals of the designed space (or design plan). This embodiment offers architects and designers a powerful tool to streamline the alignment with environmental impact goals verification process, reducing the risk of oversights and ensuring that every aspect of the path of egress aligns with regulatory standards.

### User Interaction and Experience

In some embodiments, the present invention includes a controller operative to analyze a building described via one or more of: a floorplan, two-dimensional reference, and/or Revit® compatible file, to ascertain whether the building described possesses a set of conditions useful to determine alignment with environmental impact goals. In addition, in some embodiments, a process executed by an AI engine may ascertain building attributes and analyze the building attributes that may be modified in order to bring the building into alignment with environmental impact goals. A user interface may present suggested modifications to a user. Some embodiments may also include designation and/or ranking of variables that may be modified in order to bring a building into alignment with environmental impact goals. By way of non-limiting example, variables may relate to one or more of: magnitude of structural changes, cost to implement changes, time to implement changes, impact of a change(s) on a desired use of the building, and duration of a proposed change.

In another aspect, in some embodiments, suggested modifications may be ranked according to a priority ranking of features input via a user interface. For example, a user may input priority rankings that dictate that a number of a certain type of room or unit may be maintained above a threshold within the plan, such as, for example, the plan may include: ten residential units, each unit with three bedrooms and two bathrooms and a kitchen a living room; or at least four units with three bedrooms each; a second priority may include room sizes of a minimum and/o maximum size; a third priority may include a washer and dryer area; a fourth priority may include a common area of a minimum size; and other prioritized attributes to be included in a building design. AI and/or user input may modify a design of the building to bring the building into alignment with environmental impact goals while also adhering to the priority ranking of features. In such instances, the environmental impact analysis may incorporate user-defined priorities, offering automated revision suggestions to the design plan, minimizing alterations to both spatial configurations and designated priorities. The aim is to preserve user priorities to the greatest extent possible while ensuring adherence to alignment with environmental impact goals.

Still further, in some embodiments, the controller may assess how assignment of different classes of space to one or more designated areas may alter conformance of a design with a specified environmental impact objective. Furthermore, in some embodiments, particular attributes of a building may be analyzed based upon customary practices, laws, or regulations in effect within a geopolitical boundary encompassing the building. In some embodiments, multiple disparate user interfaces may be used to communicate calculated parameters associated with determined attributes in order to give a user an improved experience while determining alignment with environmental impact goals of a given design plan, as well as changes in a determination of alignment with environmental impact goals based upon a change in one or more of the building attributes.

In an example, a user interface may be designed for an optimal user experience in evaluating an existence (or non-existence) of attributes necessary in order for a design plan to be in alignment with environmental impact goals. In some embodiments a design may be evaluated by any of the various processes as have been described herein. After a design plan is received into a controller, an interface may be presented to a user to allow for interactive assessment of attributes required for alignment with environmental impact goals. The alignment with environmental impact goals of an existing (already built) building's design plan can also be evaluated, accompanied by tailored alteration or revision suggestions. Moreover, the system may offer a comprehensive assessment, including estimates for associated costs, materials, and labor, aligned with the proposed alterations to the building.

Referring now to FIG. 12, in some embodiments, an environmental impact objective may include or otherwise be related to a LEED certification (Leadership in Energy and Environmental Design) or other designation. A LEED certification or other environmental impact objective may be directed to a Green building including an effort to amplify positive and mitigate negative variables throughout the life cycle of a building. An environmental impact objective may build upon classical building design goals of economy, utility, durability, and comfort. By enlarging the scope in this way, green building aided by the AI Engine may provide more robust frameworks to incorporate three pillars of sustainability (people, planet, and prosperity) in a construction project.

An environmental impact objective may be involved in one or more of: planning, design, construction (and demolition), and operation of building or other structure with weighted considerations, such as, one or more of: energy use, water use, indoor environmental quality, material selection, site, and location within the surrounding community. Such elements may make up the basic parameters for the different credit categories within the LEED green building rating system. LEED acts as a framework for decision-making for project teams in all of these areas, rewarding best practices and innovation and recognizing exemplary projects with different levels of LEED certification.

Referring now to FIG. 13, additional variables that may be considered include those related to Life Cycle Impact Assessment (LCA or LCIA). Environmental impact categories for Life Cycle Impact Assessment include one or more of: Eutrophication: the potential impact of substances that contribute to excessive nutrient richness in a body of water; Acidification: the transformation of air pollutants into acids that decrease the pH value of rainwater and fog; Abiotic Depletion: The depletion of finite resources and the resulting environmental implications; Greenhouse Gas: a capacity of greenhouse gases to trap infrared radiation, which is one of the earliest effects of climate change; Carbon Footprint: an outcome of an impact assessment for the environmental impact category of global warming potential; climate change, ozone depletion, human toxicity, respiratory inorganics, ionizing radiation, ecotoxicity, photochemical ozone formation, land use.

Stages involved in an environmental impact objective involving LCA may include, one or more of: product stage 1301; construction stage 1302; use stage 1303 (sometimes referred to as deployment); end of life stage 1304; and beyond system boundary 1305.

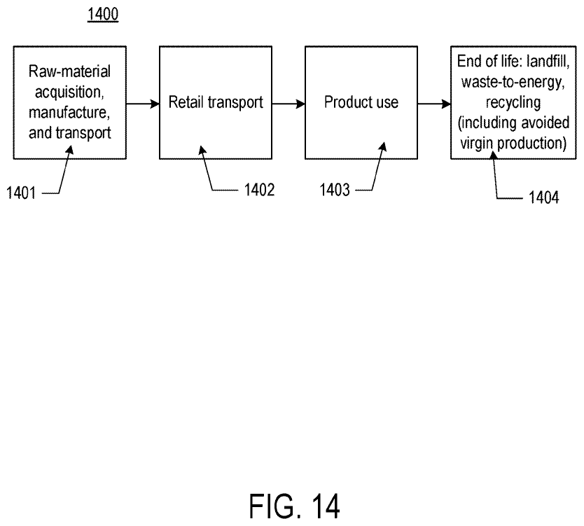

Referring now to FIG. 14, an environmental impact objective may also involve one or more variables relating to material choice, such as, by way of non-limiting example, one or more of: raw material acquisition 1401; transportation of the materials 1402; material and/or product use 1403; and material endo of life 1404.

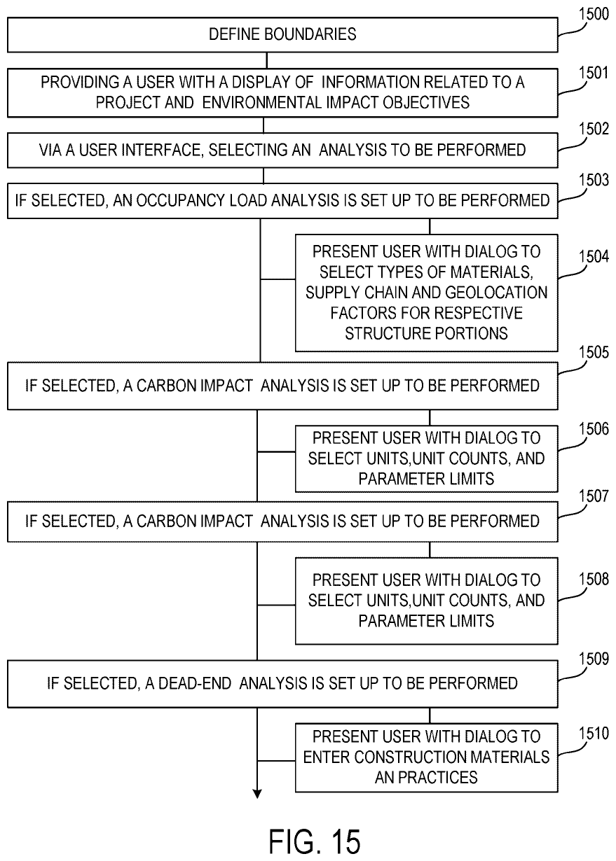

Referring now to FIG. 15, exemplary method steps that may be completed in accordance with the present invention are illustrated. The method steps may be part of a user experience.

At step 1500, boundaries may be defined.

At step 1501, the user may be provided with a user interactive interface that display project information including building attributes that are included in a determination of alignment with environmental impact goals, such as for example, a LEEDS certification.

At step 1502, the user may select an analysis to be performed. In some embodiments, the options for the analysis may include an analysis of a building for attributes that pertain to, one or more of: occupancy load, travel distance, a common path, dead end paths, and egress capacity of the spaces described in a design plan (or other reference). In some examples, multiple analyses or all offered analysis may be chosen by the user. Since a choice of all analysis may proceed through all example analysis, the example in the illustration will proceed with this choice.

At step 1503, a first analysis of occupancy load may be performed.

At step 1504, in some examples, the user may decide on the types of space to be used along with types of materials, supply chain factors, and structure portion factors. In some examples, the user may enter descriptions and factors manually. In other examples, a drop-down dialog may be presented to the user for them to choose the space types. In some examples, the user may enter associated occupant load factors. In other examples, an automatic look up of the space's associated occupant load factor may occur with a choice of the type of space. In some examples, an associated standard to be used for appropriate regions may be displayed to the user. In some embodiments, optical character recognition may be performed on located environmental impact documents to look up the factors automatically. As well, as mentioned in some examples, the user may input the types of area or materials for a structure design, while in other examples algorithms may be used to automatically classify areas by type.

At step 1505, a second analysis of environmental impact, such as for example carbon impact, may be performed.

At step 1506, the UI/UX may present the user with a dialog to allow the user to input units along with a number of those unit types and limits, such as the maximum inside, maximum outside, and total values. In some examples, the limit values may be automatically chosen. The limits may comprise just a max total value, or a combination of max total as well as max inside, or in some examples a max inside, a max outside, and a max total limit value. In an example there may be residential units with different limit values than commercial units.

At step 1507, a third analysis may be performed for the structure.

At step 1508, the user may input values associated with the structure which in some examples may be the same values input at step 1506.

At step 1509, a type of environmental impact analysis, such as carbon impact, may be chosen and performed.

At step 1510, the user may input construction materials and practices that may be used to assess adherence. In other examples, these dead-end max limits may be automatically entered based on an environmental impact objective type that is chosen for the design and analysis.

In some examples, the design may be presented to the users along with icons, buttons and other active features that may allow the user to adjust the design, and the AI extracted feature elements. There may also be icons, buttons, and other features to activate chosen analysis types to be performed. The process may loop back to an earlier step or conclude.

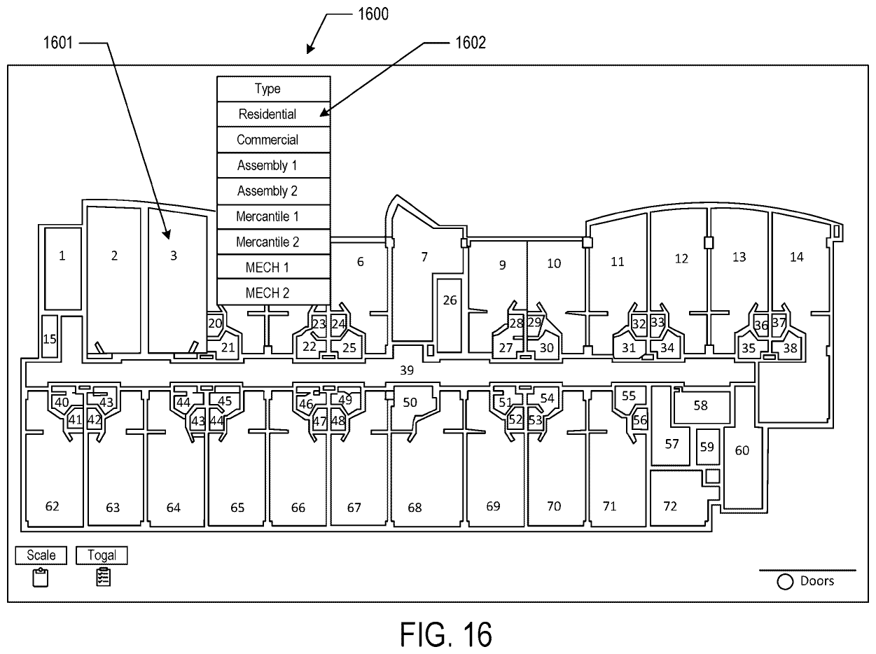

Referring now to FIG. 16, an example of classification of areas through dialogs is illustrated. An inputted design may be analyzed and the various extracted elements such as room spaces, walls, and the like may be defined in the model. The resulting space model may be displayed to the user in display 1600. Individual spaces 1601 may be coded, such as via different patterns of colors in various manners. In an example, a color such as green may indicate a space that is not allocated as a specific type. One or both of an AI engine and a user may consider a space 1601 delineated, for example, as one or more polygons and/or arcuate. An AI engine may automatically designate a type to be allocated to the space, a user may interact with the interactive user interface to designate a type of space, such as, for example via a drop-down menu 1602 which may allow the user to select a type for a selected individual or combine space 1601. As illustrated in the drop-down menu 1602, the different space types may have different pictorial designations to indicate different types of spaces. The user may use these interfaces to assign a type to each of the individual spaces that the analysis has identified.

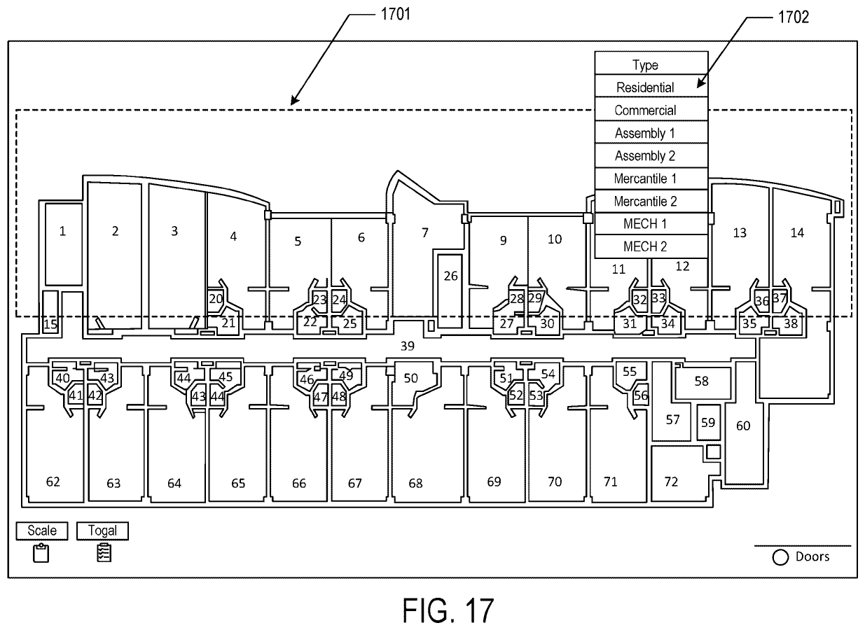

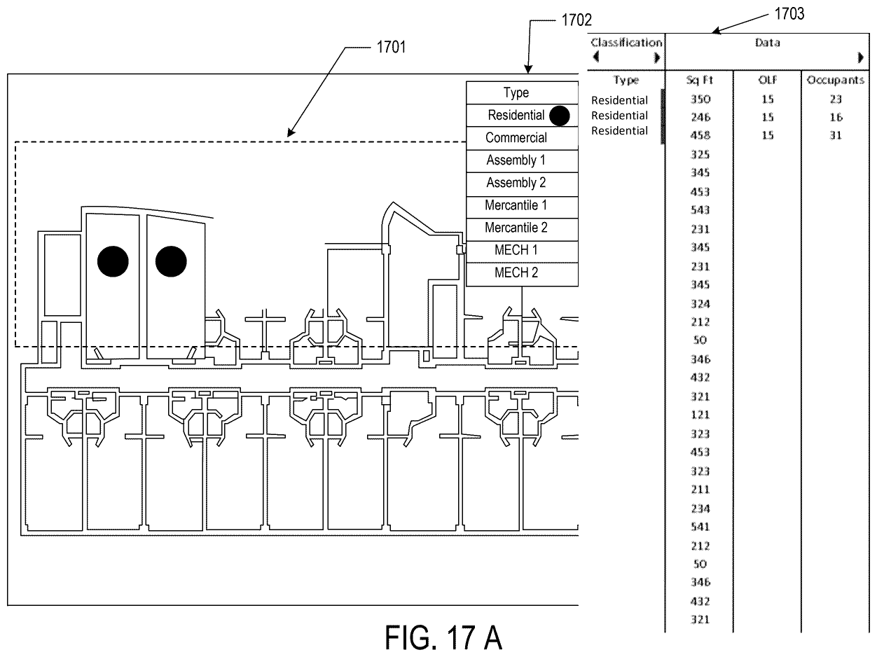

Referring now FIG. 17, in some examples, one or both of an AI engine and a user may designate multiple spaces at once that are the same space type. In an example, one or both of an AI engine and a user may create a regional boundary 1701 that surrounds multiple identified spaces. The AI engine and the user may select a space type from a predefined list of types 1702 or designate a new space type.

Referring now to FIG. 17A, in some examples, a tabular display 1703 of the spaces along with assigned types may be displayed. Once the areas are classified, other analysis types may be performed and displayed such as occupancy load, dead end, and egress capacity analysis as non-limiting examples.

An analyzed design with identified discrete spaces may be analyzed to extract the area of identified spaces of the same type. The analysis may continue to use the analyzed values such as the area, as well as parameters entered by the user. Different spaces may include residential spaces, corridors, and commercial spaces as an example.

As in other processes described herein, one or both of an AI engine, and/or a user, may designate one or more of: regions, areas, and spaces into separate units such as unit one 2006, and each unit may include one or more internal spaces. An AI engine may execute software to perform AI analysis on the floorplan to determine which region, area, or space (if any), comprises a particular material or construction practice.

In the examples provided, and in general, a user interface may allow for the user to access and display applicable environmental impact objectives to the analysis selected as well as, in some examples, to regional location of the design under analysis. In some examples, the applicable code may be accessed from a database in logical communication with the controller. In other examples, the systems of the types described herein may access online data sources and may interpret code sources by analyzing graphical sources and files such as with optical character recognition.

In displaying and listing an environmental impact objective, a user interface of the system may highlight portions of the display of a design plan which illustrate relevant aspects of that environmental impact objective and the status of adherence to the objective. In some examples, color shading, blinking or the like may be manners to provide such highlighting.

In some examples, where there are non-adherent aspects, a trained artificial intelligence analysis of numerous examples of non-adherent designs and their subsequent design changes that remediated the issues may be used to suggest modifications based on an analysis of the design under review. In other examples, other algorithms may be used to provide such suggestions, such as by review of databases which track common required changes to make a building conform to requirements. Examples of improvements which the system may recommend to a user may include reducing an amount of materials utilized; a change in a material type utilized; a change in a source of materials utilized; a change in a construction practice; a change in a design of a structure to be built; and a change in a size of a structure to be built. Environmental impact may also include an amount of energy or other consumable used, such as in heating and colling and/or maintenance of a structure.

Highlighting, such as in the ways previously described, may be used to indicate one or both points of adherence and points of non-adherence. The relevant portions of the code may be displayed such as in an overlay, or a pop-up window and may be matched in various manners to the design under analysis, such as with coloration as a non-limiting example. Alternatively, points of non-adherence may be highlighted (e.g., using color coding scheme as discussed above in some embodiments). These aspects of the user interface experience may improve effectiveness and/or efficiency for inspectors by providing this highlighting or other summarization of points of adherence and points of non-adherence.

Other tools may also be provided through the user interface experience to support users such as, for example, allowing the user to click and drag a cursor over a space designated as a room. Various symbols and icons may be overlayed on the design to indicate various artifacts, corners, stairs, measurements such as door width, access to measurements or design data of various kinds and the like. The user may be able to zoom to portions of the drawing for more detailed review and/or the display of more detailed measurements and design data. Furthermore, the user may be able to zoom to features such as in a non-limiting example a doorway to allow a check of calibration of the scale of the design or even a recalibration of the scale, where such a recalibration may drive a reassessment of adherence by the system.

### Additional Methods of Model Formation

There may be alternative methods of receiving data from various sources that can be used to generate a design or to supplement a design created in the manners as have been described previously. For example, the system may receive an architectural file with intelligent features of various kinds, which will be discussed in further detail following. The present system may operate in concert with a BIM or CAD design system, for example, as an add-in to these design systems, and then the present system may have access to design elements, location data and the like directly. In other examples, the present system may access BIM or CAD design system data by loading data files from said systems. In still further examples, the present system may operate to capture data from display screens that are displaying designs from the said BIM or CAD design systems. As an additional example, the present adherence assessment system exhibits its versatility by harmoniously integrating with prominent design frameworks like BIM or CAD. This integration facilitates a proactive approach to evaluate the adherence of building designs in the nascent or initial stages of the creative process, considering an array of potential environmental impact objectives. This early-stage assessment not only ensures that the design in progress aligns with regulatory standards but also serves as a strategic time-saving measure, optimizing the efficiency of the overall design workflow. The synergy between adherence analysis and design systems not only enhances the precision of the evaluation at early stages but also contributes to a more streamlined and resource-efficient architectural and engineering endeavor.

In a non-limiting example, the present system may receive a file in one of the REVIT native formats such as files of types RVT, RFA, RTE and RFT. Embodiments may also include receiving non-Revit compatible file formats, such as, one or more of: BMP, PNG, JPG, JPEG, and TIF.

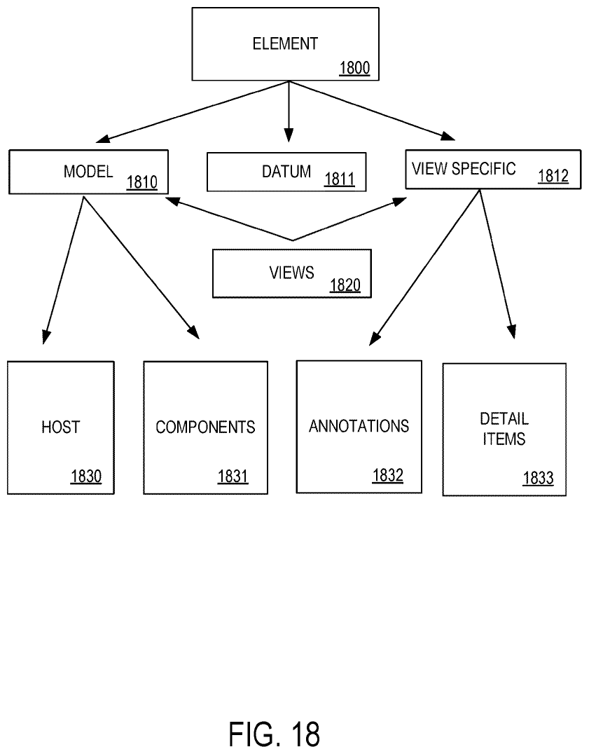

Referring now to FIG. 18, a high-level review of the type of information that may be stored in such a filetype is provided, in general, for Revit file types. As shown, the datafile may include objects that may be considered elements 1800. The elements may be of different types such as model elements, datum elements and view-specific elements. Model elements 1810 may correspond to physical elements that are constructed. These may include, amongst others, such elements as floors, walls, ceilings, walls that include structural support aspects, roofs, and the like which may be considered “Hosts” 1830. Other model elements 1800 may include components 1831. Components 1831 may include features such as windows, doors and cabinets and the like. Components may also include beams, braces, and structural columns amongst other such features. An artificial intelligence-based analysis system may be used to load such features from a file and recognize their content and context based upon direction information in the file as well as learned aspects.

The Datum elements 1811 may include aspects that define the design context. These may include contextual support such as definition of grids, which in some cases may be used to “snap” elements or components to. The Datum elements 1811 may also include levels which may organize components and elements into similar groups. The Datum elements 1811 may include reference planes to support specifically locating and placing elements and components in a design.

The files may also include view-specific elements 1812. View specific elements may be details and annotation elements that appear only when specific views 1820 are activated. Annotation elements 1832 may include keynotes, comments, tags, dimensions, and other such annotations. Detail elements 1833 may include detail lines, filling of various aspects and other such components.

These various elements may be loaded from exemplary files and extracted for their relevant information. Other file types in addition to the Revit® types previously mentioned may include in a non-limiting sense DGN, DWF, DWG, DXF, IFC, SAT, SKP, ODBC, HTML, TXT, and gbXML file types. As mentioned, systems of the present type may be configured to extract information based on defined file structure of the input file times. In addition, learned aspects may be applied to interpret the designs and assign components or alter certain information about a component. For example, a wall definition may be recognized by the present system and have aspects of it modified, and additional model aspects defined such as an appropriate center line defined, or a set of different dividing line types assigned. The wall may have a designation assigned such as whether it is an internal or external wall. Other such learned assignments may be applied after data is loaded from an external file. As mentioned, the present system may also operate in manners where it has access to objects of the BIM or CAD design system directly as an add-in, or a parallel running system with access to memory locations running in the BIM or CAD design system. Still further examples may derive from capturing design elements in displays of various kinds. Finally, such access to external file types may be used to verify models generated in the standard manners as have been described or add information such as annotations, descriptions, and other such aspects.

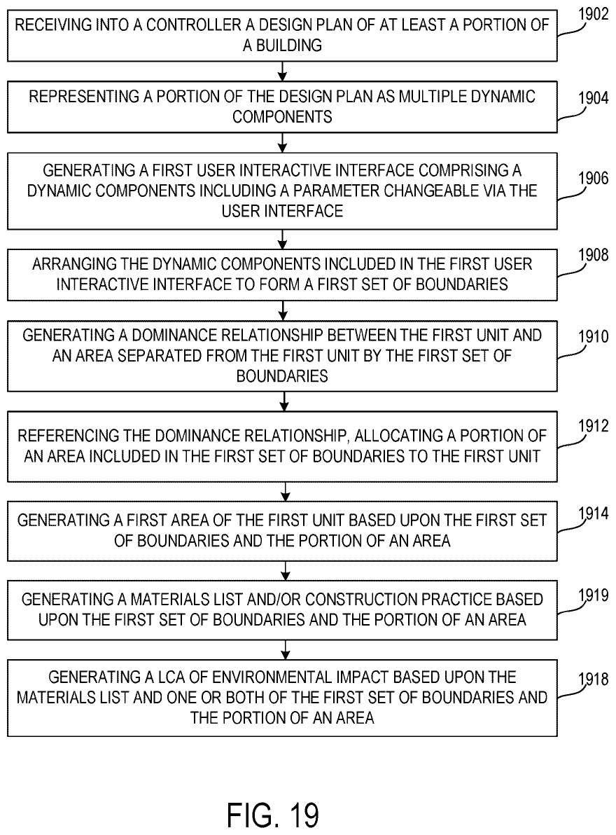

FIG. 19 illustrates a flowcharts that describes method steps according to some embodiments of the present disclosure. According to the present invention, a method of practice may include the steps of, at step 1902, receiving into a controller a design plan of at least a portion of a building.

At step 1904, the method may include representing a portion of the design plan as multiple dynamic components.

At step 1906, the method may include generating a first user interactive interface including at least some of the multiple dynamic components representing portion of the design plan, each dynamic component including a parameter changeable via the user interactive interface.

At step 1908, the method may include arranging the dynamic components included in the first user interactive interface to form a first set of boundaries, the first set of boundaries including a respective length and area, and the first set of boundaries defining at least a portion of a first unit.

At step 1910, the method may include generating a dominance relationship between the first unit and an area separated from the first unit by the first set of boundaries.

At step 1912, the method may include referencing the dominance relationship, allocating a portion of an area included in the first set of boundaries to the first unit. At step 1914, the method may include generating a first area of the first unit based upon the first set of boundaries and the portion of an area included in the first set of boundaries that may be allocated to the first unit.

At step 1916, the method may include generating a materials list and/or a construction practice based upon a first of boundaries and the portion of an area. At step 1918, the method may include generating a LCA of environmental impact based upon the materials list and one or both of the first set of boundaries and the portion of an area.

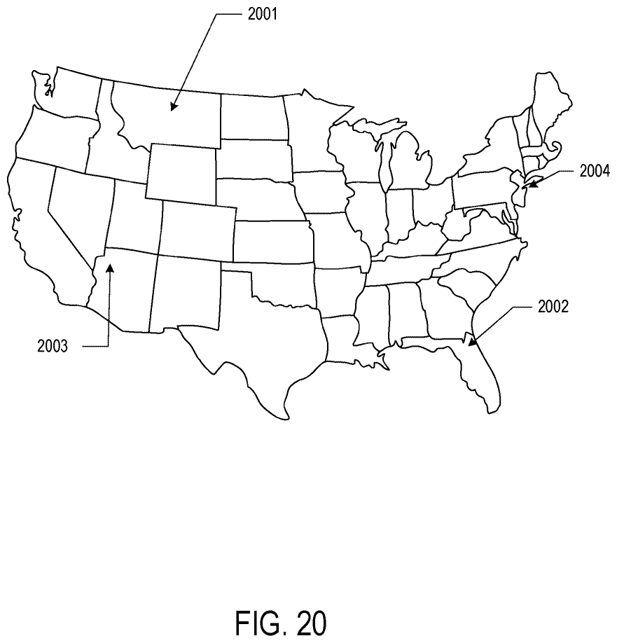

Referring now to FIG. 20, in some embodiments an environmental impact objective may be based upon, and/or include variables relating to a geographic area and/or geopolitical area. For example, a cold environment associated with a first geographic area 2001, may have different environmental impact objectives than a hot and humid environment in second geographic area 2002, which may in turn have different environmental impact objectives than a hot and dry environment in third geographic area 2003, and a metropolis geopolitical area 2004 may have still different variables and requirements and objectives.

In some embodiments, the method may additionally include determining a scale of the components included in the design plan and/or referencing the dynamic components and determining a width of one or more of: a path of egress, a doorway, and a stairwell.

In some embodiments, the method may also include training the AI engine via a human identifying portions of the design plan as a particular type of component and associating a pattern of pixels with the portions of the design plan.

Another aspect may include generating suggested modifications to a design plan in order to meet adherence with a set of conditions. Modifications may include, by way of non-limiting example, including a doorway, changing a length of a wall, widening the path of egress, eliminating a dead end, such as, for example, via inclusion of an additional wall.

In some embodiments, some steps of the processes described herein may be repeated for multiple units included in a design plan. For example, the steps of: arranging the dynamic components included in the first user interactive interface to form a first set of boundaries, the first set of boundaries comprising a respective length and area, and said first set of boundaries defining at least a portion of a first unit; generating a dominance relationship between the first unit and an area separated from the first unit by the first set of boundaries; referencing the dominance relationship, allocating a portion of an area included in the first set of boundaries to the first unit; generating a first area of the first unit based upon the first set of boundaries and the portion of an area included in the first set of boundaries that is allocated to the first unit; calculating an occupancy load for the first unit based upon the first area of the first unit; and with the controller, referencing the length of the first set of boundaries and calculating a distance from a designated point included in the first unit; may be repeated multiple times for multiple respective units.

In some embodiments, a geopolitical locality may be determined, and a set of conditions specified, in a supply chain process to the situs of the building or other structure to be constructed may be used in the methods described.

A design plan may be received into an AI controller and/or other controller as input for one or more of: AI, machine learning and logical analysis. As with other architectural aspects, illustrated aspects may be ascertained via AI processes and/or machine learning processes from a 2D or 3D representation of a building, or a portion of a building, or other structure. Automated processes may reference one or more of: AI and machine learning determined architectural aspects, sizes, distances, areas, heights, vertical opening, and/or combine them with user inputs to assess adherence with an environmental impact goal.

Vertical openings may generally be treated as an opening between two or more floors (stories) in a building. They have a variety of uses and functions including, but not limited to: movement of occupants between floors during normal use and emergency use; exit stairs; convenience stairs/opening (limited to two floors); elevator shafts; installation of building services and features that serve multiple floors; plumbing systems; electrical systems (including telecom, data); heating/air conditioning ducts; fire protection equipment; trash and linen chutes; expansion/seismic joint; aesthetic value; communicating space; and atriums.

Some vertical openings have a same fundamental requirement regarding fire resistance rated construction stresses. Other types of vertical openings have special rules that do not require enclosure but rather a layer in added fire protection and safety features. The present invention allows for AI and machine learning processes to determine an existence of vertical openings, and the automated processes apply an appropriate set of rules to the determined vertical openings.

Automated processes apply logic to indicate whether it matters where the vertical openings occur in the building. Examples of treatment of vertical openings and treatments are included in the table below:

### Glossary

“Artificial Intelligence” as used herein means machine-based decision making and machine learning including, but not limited to: supervised and unsupervised recognition of patterns, classification, and numerical regression. Supervised learning of patterns includes a human indicating that a pattern (such as a pattern of dots formed via the rasterization of a two-dimensional image) is representative of a line, polygon, shape, angle or other geometric form, or an architectural aspect, unsupervised learning can include a machine finding a pattern submitted for analysis. One or both may use mathematical optimization, formal logic, artificial neural networks, and methods based on one or more of: statistics, probability, linear regression, linear algebra, and/or matrix multiplication.

“AI Engine” as used herein an AI Engine (sometimes referred to as an AI model) refers to methods and apparatus for applying artificial intelligence and/or machine learning to a task performed by a controller. In some embodiments, a controller may be operative via executable software to act as an AI engine capable of recognizing aspects and/or tally aspects of a design plan that are relevant to generating an estimate for performing projects included in construction of a building or other activities related to construction of a building.

“Computer Aided Design,” sometimes referred to as “CAD,” as used herein shall mean the use of automation for the creation, modification, analysis, or optimization of a design plan or design plan file.

“Building Information Modeling” sometimes referred to as “BIM,” as used herein.

“Smoke” as used herein, means a concentration of an aerosol including airborne particulates and gases resulting from a material undergoing combustion or pyrolysis, combined with a quantity of air that is drawn along with the airborne particulates and gases. Smoke may also mean various gases, including carbon dioxide, carbon monoxide, and other pollutants, often carrying with them hazardous chemicals.

“Vector File” as used herein a vector file is a computer graphic that uses mathematical formulas to render its image. In some embodiments, a sharpness of a vector file will be agnostic to size within a range of sizes viewable on smart device and personal computer display screens.

Typically, a vector image includes segments with two points. The two points create a path. Paths can be straight or curved. Paths may be connected at connection points. Connected paths form more complex shapes. More points may be used to form longer paths or closed shapes. Each path, curve, or shape has its own formula, so they can be sized up or down and the formulas will maintain the crispness and sharp qualities of each path.

A vector file may include connected paths that may be viewed as graphics. The paths that make up the graphics may include geometric shapes or portions of geometric shapes, such as: circles, ellipsis, Bezier curves, squares, rectangles, polygons, and lines. More sophisticated designs may be created by joining and intersecting shapes and/or paths. Each shape may be treated as an individual object within the larger image. Vector graphics are scalable, such that they may be increased or decreased without significantly distorting the image.

The terms “design plan,” “building plan,” “building design,” “floor plan,” “two-dimensional reference,” “two-dimensional representation,” or simply “design” are used interchangeably, often referring to the same or similar concepts in the context of architectural or construction documentation.

The methods and apparatus of the present invention are presented herein generally, by way of example, to actions, processes, and deliverables important to industries such as the construction industry, by generating improved determination of adherence with an environmental impact objective, based on inputted design plans, floor plans or other construction related diagrams, however, design plans may include almost any artifact that may be converted to a pixel pattern.

Some specific embodiments of the present invention include input of a design plan (e.g., a blueprint, design plan floorplan or other two-dimensional artifact) so that it may be analyzed using artificial intelligence and used to generate a determination of adherence with specified conditions included in one or multiple environmental impact objectives in a short time period. However, unless expressly indicated in an associated claim, the present invention is not limited to analysis of design plans for any particular industry. The examples provided herein are illustrative in nature and show that the present invention may use controllers and/or neural networks and artificial-intelligence (AI) techniques to identify aspects of a building described by a design plan and specify quantities for variables used to generate a bid or other proposal for completion of a project (or some subset of a project) represented by the design plan. For example, aspects of a building that are identified may include one or more of: walls or other boundaries; doorways; doors; plumbing; plumbing fixtures; hardware; fasteners; wall board; flooring; a level of complexity and other variables ascertainable via analysis of the design plan. AI analysis provides values for variables used in estimations involved in a project bidding process or related activity.

The present invention provides for systems of one or more computers that can be configured to perform particular operations or actions by virtue of having software, firmware, hardware, or a combination of them installed on the system that in operation causes or cause the system to perform the actions. One or more computer programs can be configured to perform artificial intelligence operations or actions by virtue of including instructions that, when executed by data processing apparatus, cause the apparatus to perform the actions.

### CONCLUSION

A number of embodiments of the present disclosure have been described. While this specification contains many specific implementation details, they should not be construed as limitations on the scope of any disclosures or of what may be claimed, but rather as descriptions of features specific to particular embodiments of the present disclosure. While embodiments of the present disclosure are described herein by way of example using several illustrative drawings, those skilled in the art will recognize the present disclosure is not limited to the embodiments or drawings described. It should be understood the drawings, and the detailed description thereto are not intended to limit the present disclosure to the form disclosed, but to the contrary, the present disclosure is to cover all modification, equivalents and alternatives falling within the spirit and scope of embodiments of the present disclosure as defined by the appended claims.

The headings used herein are for organizational purposes only and are not meant to be used to limit the scope of the description or the claims. As used throughout this application, the word “may” be used in a permissive sense (e.g., meaning having the potential to), rather than the mandatory sense (e.g., meaning must). Similarly, the words “include,” “including,” and “includes” mean including but not limited to. To facilitate understanding, like reference numerals have been used, where possible, to designate like elements common to the figures.

The phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted the terms “comprising,” “including,” and “having” can be used interchangeably.

Certain features that are described in this specification in the context of separate embodiments can also be implemented in combination in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while method steps may be depicted in the drawings in a particular order, this should not be understood as requiring that such operations be performed in the particular order shown or in a sequential order, or that all illustrated operations be performed, to achieve desirable results.

Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. £ Other embodiments are within the scope of the following claims. In some cases, the actions recited in the claims can be performed in a different order and still achieve desirable results. In addition, the processes depicted in the accompanying figures do not necessarily require the particular order show, or sequential order, to achieve desirable results. In certain implementations, multitasking and parallel processing may be advantageous. Nevertheless, it will be understood that various modifications may be made without departing from the spirit and scope of the claimed disclosure.

What is claimed is:

1. A method for efficiently managing environmental aspects within a building based upon artificial intelligence analysis of a design plan, the method comprising the steps of:
a. receiving into a controller the design plan of at least a portion of the building;
b. representing at least one portion of the design plan as multiple dynamic components;
c. generating a first user interactive interface comprising at least some of the multiple dynamic components representing the at least one portion of the design plan, each of the multiple dynamic components including a parameter changeable via the first user interactive interface;
d. receiving a user input into a first user interface selection of at least some the multiple dynamic components;
e. generating a materials list involved in constructing the first user interface selection of at least some the multiple dynamic components; and
f. referencing the materials list, indicating in the first user interactive interface, an environmental impact criteria associated with constructing a first area.

2. The method of claim 1, further comprising the steps of: calculating LEED certification qualification as part of an environmental impact, and displaying the LEED certification qualification in the first user interactive interface.

3. The method of claim 1, further comprising the steps of: calculating an LCA environmental impact analysis as part of the environmental impact criteria, and displaying the LCA environmental impact analysis in the first user interactive interface.

4. The method of claim 3, further comprising a step of aggregating areas of multiple units included in the design plan and determining the environmental impact criteria of constructing the aggregated areas of the multiple units.

5. The method of claim 1, further comprising a step of displaying at least one automated suggestion related to the multiple dynamic components and an environmental impact aspect.

6. The method of claim 3, additionally comprising the steps of determining a geopolitical locality and an authority having jurisdiction over a situs of the building; and including in the LCA environmental impact analysis, preferences of the authority having jurisdiction.

7. The method of claim 5, wherein the at least one automated suggestion comprises at least one of: a proposed design alteration, a dimension adjustment, a length and width suggestion, a material specification, and a source of materials.

8. The method of claim 5, further comprising a step of displaying in the first user interactive interface an advertisement comprising at least one of: a dynamic component from a particular brand, an alternative dynamic component from a different brand, a list of materials with pricing and purchase options, a contact information of a contractor available for hire, and a contact information of an architect available for hire.

9. The method of claim 1, additionally determining a scale of the multiple dynamic components included in the design plan.

10. The method of claim 1, additionally comprising a step of generating a user interface comprising user interactive areas operative to change at least one of: a size and shape of at least one of the multiple dynamic components thereby changing at least one of: the first area of a first unit and an amount of a material, placing the building in adherence with the environmental impact criteria.

11. The method of claim 10, wherein at least one of the multiple dynamic components comprises a polygon and the method further comprises the steps of: receiving an instruction via the first user interactive interface to modify a parameter of the polygon; modifying the parameter of the polygon based upon the instruction received via the first user interactive interface; and changing the first area of the first unit based upon the modifying of the parameter of the polygon.

12. The method of claim 11, wherein the modified parameter of the polygon comprises an area of the polygon.

13. The method of claim 11, wherein the modified parameter of the polygon comprises a shape of the polygon.

14. The method of claim 11, wherein at least one of the multiple dynamic components comprises a line segment and the method further comprises the steps of:
receiving an instruction via the first user interactive interface to modify a parameter of the line segment; modifying the parameter of the line segment based upon the instruction received via the first user interactive interface; changing a material amount to be used in the environmental impact criteria.

15. The method of claim 14, wherein the parameter of the line segment comprises a length of the line segment and the method additionally comprises a step of modifying a length of a wall based upon modifying the length of the line segment.

16. The method of claim 1, further comprising a step of integrating a BIM or CAD design system so that adherence of the design plan can be assessed during early stages of designing the design plan.

17. The method of claim 16, wherein determining the adherence of the design plan of the building comprises determining the adherence based on the artificial intelligence analysis of the design plan by an AI engine.

18. The method of claim 17, further comprising a step of training the AI engine through at least one of: based on human inputs, based on thousands of design plans, and previous adherence analysis of design plans.

19. An apparatus comprising:
a processor; and
a memory storing executable software code, wherein the executable software code,
when executed by the processor, causes the apparatus to:
(a) receive into a controller the design plan of at least a portion of a building;
(b) represent at least one portion of the design plan as multiple dynamic components;
(c) generate a first user interactive interface comprising at least some of the multiple dynamic components representing the at least one portion of the design plan, each of the multiple dynamic components including a parameter changeable via the first user interactive interface;
(d) receive a user input into a first user interface selection of at least some of the multiple dynamic components;
(e) generate a materials list involved in constructing the first user interface selection of at least some of the multiple dynamic components; and
(f) reference the materials list, indicating in the first user interactive interface, an environmental impact criteria associated with constructing a first area.

20. The apparatus of claim 19, wherein the executable software code, when executed by the processor, further causes the apparatus to:
(g) calculate LEED certification qualification as part of an environmental impact; and
(h) display the LEED certification qualification in the first user interactive interface.

21. The apparatus of claim 19, wherein the executable software code, when executed by the processor, further causes the apparatus to:
(i) calculate an LCA environmental impact analysis as part of the environmental impact criteria; and
(j) display the LCA environmental impact analysis in the first user interactive interface.

22. The apparatus of claim 21, wherein the executable software code, when executed by the processor, further causes the apparatus to:
(k) aggregate areas of multiple units included in the design plan; and
(l) determine the environmental impact criteria of constructing the aggregated areas of the multiple units.
